(19) United States
(12) Patent Application Publication
(10) Pub. No.: US 2014/0183960 A1
(43) Pub. Date: Jul. 3, 2014

(54) PHOTOVOLTAIC POWER GENERATION SYSTEM

(71) Applicants: Dhanushan Balachandreswaran, Richmond Hill (CA); John Paul Morgan, Toronto (CA)

(72) Inventors: Dhanushan Balachandreswaran, Richmond Hill (CA); John Paul Morgan, Toronto (CA)

(73) Assignee: Morgan Solar Inc., Toronto, ON (CA)

(21) Appl. No.: 14/125,171

(22) PCT Filed: Jun. 22, 2012
(86) PCT No.: PCT/IB2012/053174

§ 371 Date: Mar. 11, 2014

Related U.S. Application Data
(60) Provisional application No. 61/499,978, filed on Jun. 22, 2011.

(51) Int. Cl. H02M 7/42; H02J 1/10; H01L 31/042

(52) U.S. Cl. CPC H02M 7/42; H01L 31/042; H02J 1/102
USPC 307/82; 363/13

(57) ABSTRACT

A photovoltaic (PV) power generation system comprising an array of PV cell modules arranged in strings connected via secondary stage power efficiency optimizers to a central inverter is provided. In at least one of the strings, sunlight receiver assemblies (including the PV cells) of the PV cell modules are provided each with a corresponding primary stage or integrated power efficiency optimizer to adjust the output voltage and current of the PV cell. The PV cell modules can, but need not include optical concentrators.

### REFERENCE TO PRIOR APPLICATIONS

This application claims priority to U.S. Application No. 61/499,978, filed Jun. 22, 2011, entitled “An Integrated Photovoltaic Module”, the entirety of which is incorporated herein by reference.

### TECHNICAL FIELD

The present application relates to the field of solar energy. In particular, the present application relates to photovoltaic power generation systems.

### BACKGROUND

Despite the natural abundance of solar energy, the ability to efficiently harness solar power as a cost-effective source of electrical power remains a challenge.

Solar power is typically captured for the purpose of electrical power production by an interconnected assembly of photovoltaic (PV) cells arranged over a large surface area of one or more solar panels. Multiple PV solar panels may be arranged in arrays.

A longstanding problem in the development of efficient solar panels has been that the power generated by each string of PV cells is limited by the lowest performing PV cell when the PV cells act as current sources. Similarly, an array of solar panels is limited by its lowest performing solar panel when the solar panels are connected in series. Thus, a typical solar panel can underperform when the output power of the solar panel differs from other solar panels of the array it supports. The ability to convert the solar energy impinging upon a PV cell, panel or array is therefore limited, and the physical integrity of the solar panels may be compromised by exposure to heat dissipated due to unconverted solar energy.

PV cells of a string may perform differently from one another due to inconsistencies in manufacturing, and operating and environmental conditions. For example, manufacturing inconsistencies may cause two otherwise identical PV cells to have different output characteristics. The power generated by PV cells is also affected by external factors such as shade and operating temperature. Therefore, in order to make the most efficient use of PV cells, manufacturers bin or classify each PV cell based on their efficiency, their expected temperature behaviour and other properties, and create solar panels with similar, if not identical, PV cell efficiencies. Failure to classify cells in this manner before constructing a panel can lead to cell-level mismatches and underperforming panels. However, this assembly line classification process is time consuming, costly, and occupies a large footprint on the plant floor (as solar simulators and automatic sorting and binning machines, such as electroluminescent imaging systems, are required to characterize the PV cells), but has been crucial to improving the efficiency of solar panels.

To improve the efficiency of capturing solar radiation, optical concentrators may be used to collect light incident upon a large surface area and direct or concentrate that light onto a small PV cell. A smaller active PV cell surface may therefore be used to achieve the same output power. Concentrators generally comprise one or more optical elements for the collection and concentration of light, such as lenses, mirrors or other optically concentrative devices retained in a fixed spatial position relative to the PV cell and optically coupled to the aperture of the PV cell.

Concentrated photovoltaic (CPV) systems introduce a further level of complexity to the problem of mismatched PV cell efficiencies because inconsistencies in manufacturing, and operating and environmental conditions of optical concentrators may also degrade the performance of optical modules (the optical modules comprising the concentrator in optical communication with the PV cell). For example, point defects in the concentrator, angular or lateral misalignment between the optical concentrator and PV cell causing misdirection of the sun's image on the active surface of the PV cell, solar tracking errors, fogging, dust or snow accumulation, material change due to age and exposure to nature's elements, bending, defocus and staining affect the performance of optical modules. Furthermore, there may be losses inherent in the structure of the optical modules. For example, there may be transmission losses through the protective cover of the optical concentrator, mirror reflectivity losses, or secondary optical element losses including absorption and Fresnel reflection losses. If the efficiencies of optical concentrators within a solar panel are not matched, the performance of the panel or array will be downgraded to the level of the lowest performing optical module due to mismatching PV cell properties such as fluctuating cell output voltages and/or current.

Thus, the conventional manufacture of CPV systems requires sorting and binning of PV cells for their efficiencies and other PV properties, sorting and binning of optical concentrators and sorting and binning of optical modules, which is time consuming and expensive.

It is therefore desirable to overcome or reduce the degradation in performance due to irregularities in PV cell power output and, in the case of CPV systems, the optical concentrators, in order to improve the efficiency of solar panels and to improve the efficiency of arrays of solar panels where the performance of the constituent solar panels differ.

### BRIEF DESCRIPTION OF THE DRAWINGS

In drawings which illustrate by way of example only a preferred embodiment of the invention,

FIG. 1 is a schematic diagram of a photovoltaic power generation system having secondary stage power efficiency optimizers connected in series with a central inverter;

FIG. 2 is a schematic diagram of a photovoltaic power generation system having secondary stage power efficiency optimizers connected in parallel with a central inverter;

FIG. 3 is a schematic diagram of a photovoltaic power generation system having secondary stage power efficiency optimizers connected to a variety of different types of strings of PV cells;

FIG. 4 is a schematic diagram of a photovoltaic power generation system having second stage power efficiency optimizers connected to a bank of batteries and a DC load;

FIG. 5A is a block diagram of integrated PV cell modules with DC output connected in series;

FIG. 5B is a block diagram of integrated PV cell modules with DC output connected in parallel;

FIG. 5C is a block diagram of a matrix of integrated PV cell modules with DC output connected to a second stage power efficiency optimizer;

FIG. 6 is schematic diagram of an array of PV panels;

FIG. 7 is a perspective view of a solar panel mounted on a tracker;

FIG. 8 is a schematic diagram of an embodiment of a PV cell module;

FIG. 9 is a schematic diagram of an embodiment of a concentrating photovoltaic (CPV) module;

FIG. 10A is an elevation view of an optical concentrator;

FIG. 10B is an enlarged view of the central portion of FIG. 10A, illustrating the propagation of sunlight therein to a PV cell;

FIG. 11 is an exploded perspective view of another embodiment of an optical concentrator;

FIGS. 12A to 12I illustrate alternative embodiments of optical concentrators;

FIG. 13A is an elevation view of another embodiment of an optical concentrator;

FIG. 13B is an enlarged view of a portion of the optical concentrator of FIG. 13A;

FIG. 14A is an illustration of a sun image on a perfectly aligned PV cell;

FIG. 14B is an illustration of a sun image on a misaligned PV cell;

FIG. 15A is an illustration of a typical I-V curve of a PV cell at various operating temperatures;

FIG. 15B is an illustration of a typical P-V curve of a PV cell at various operating temperatures;

FIG. 16A is a plan view of a first side of an embodiment of a receiver assembly;

FIG. 16B is a plan view of a second side of an embodiment of a receiver assembly comprising a multi-chip integrated power efficiency optimizer;

FIG. 16C is a side view of the embodiment of the receiver assembly of FIGS. 16A and 16B;

FIG. 17 is a plan view of another embodiment of a receiver assembly comprising a integrated power efficiency optimizer system-on-a-chip;

FIG. 18 is a plan view of a first side of another embodiment of a receiver assembly;

FIG. 19 is a plan view of a first side of yet another embodiment of a receiver assembly;

FIG. 20 is a plan view of an embodiment of a receiver assembly comprising two separate printed circuit boards;

FIG. 21A is a plan view of a first side of an embodiment of a receiver assembly powered by a secondary PV cell;

FIG. 21B is a plan view of a second side of an embodiment of a receiver assembly comprising a multi-chip integrated power efficiency optimizer powered by a secondary PV cell;

FIG. 22 is a schematic of a solar panel comprising photovoltaic cells and systems-on-a-chip;

FIG. 23 is an exploded side view of an embodiment of an integrated CPV module;

FIG. 24 is a plan view of an embodiment of a string of integrated CPV modules;

FIG. 25 is a block diagram of the integrated power efficiency optimizer system;

FIG. 26 is a block circuitry diagram of an embodiment of a receiver assembly powered by the PV cell of the integrated PV cell module;

FIG. 27 is a block circuitry diagram of an embodiment of a receiver assembly powered by the PV cell of the integrated PV cell module and/or an auxiliary power source without a battery;

FIG. 28 is a block circuitry diagram of an embodiment of a receiver assembly powered by the PV cell of the integrated PV cell module and/or an auxiliary power source with a battery;

FIG. 29 is a block circuitry diagram of an embodiment of a receiver assembly with communication circuitry;

### DETAILED DESCRIPTION

The embodiments described herein provide a PV apparatus and method of converting solar power to electrical power by an array of interconnected PV cells. These embodiments provide two stages of localized power conditioning of output from a PV cell, and thereby ameliorate at least some of the inconveniences present in the prior art.

A PV power generation system and method is provided to address irregularities in performance of PV cell modules, whether due to operating and environmental conditions or manufacturing defects such as misalignments of various components within an optical concentrator (such as light guides, focusing elements and the like), misalignment between the optical concentrator and the PV cell, defects within any such component or any other anomalies, and irregularities in performance between strings of PV cell modules, and to reduce the number and size of conductors and inverters required. The system comprises an array of PV cell modules arranged in strings connected via secondary stage power efficiency optimizers to a central inverter. In at least one of the strings of the array, sunlight receiver assemblies (including the PV cell) are provided each with a corresponding primary stage or integrated power efficiency optimizer to adjust the output voltage and current of the PV cell resulting from differing efficiencies between each one of the PV cell modules.

Additional and alternative features, aspects, and advantages of the embodiments described herein will become apparent from the following description, the accompanying drawings, and the appended claims.

An embodiment provides a photovoltaic power generation system comprising a plurality of photovoltaic strings, at least one of the strings being a string of integrated photovoltaic cell modules and each module comprising a photovoltaic cell and a primary stage power efficiency optimizer in electrical communication with the photovoltaic cell, the primary stage power efficiency optimizer configured to adjust an output voltage and current of the photovoltaic cell to reduce loss of output power of the string resulting from differences in output from the integrated photovoltaic cell modules of the string; a plurality of secondary stage power efficiency optimizers, each secondary stage power efficiency optimizer electrically connected to at least one of the photovoltaic strings and configured to adjust an output voltage and current of the at least one photovoltaic string to reduce loss of output power of the system resulting from differences in output of the strings, and at least one of the secondary stage power efficiency optimizers being electrically connected to at least one of the at least one string of integrated photovoltaic cell modules; and a central inverter electrically connected to the plurality of secondary stage power efficiency optimizers.

A further aspect of an embodiment provides a photovoltaic power generation system of wherein at least one of the strings electrically connected to one of the secondary stage power efficiency optimizers comprises non-concentrated integrated photovoltaic cell modules.

A further aspect of an embodiment provides a photovoltaic power generation system wherein at least one of the integrated photovoltaic cell modules further comprises an optical concentrator.

A further aspect of an embodiment provides a photovoltaic power generation system of claim 3, wherein the optical concentrator comprises at least one focusing element and a light guide which guides light toward the photovoltaic cell.

A further aspect of an embodiment provides a photovoltaic power generation system wherein the primary stage power efficiency optimizer and the photovoltaic cell are integrated on a receiver assembly having a substrate on which the photovoltaic cell and the primary stage power efficiency optimizer are mounted, and wherein the primary stage power efficiency optimizer is disposed proximate to the photovoltaic cell.

A further aspect of an embodiment provides a photovoltaic power generation system wherein the primary stage power efficiency optimizer further comprises components selected from the group of power conversion controller, bypass controller, communication controller, system protection controller, auxiliary power source, or any combination thereof.

A further aspect of an embodiment provides a photovoltaic power generation system wherein the primary stage power efficiency optimizer comprises a voltage sensor for detecting the voltage produced by the photovoltaic cell and a current sensor for detecting the current produced by the photovoltaic cell.

A further aspect of an embodiment provides a photovoltaic power generation system wherein each primary stage power efficiency optimizer adjusts the output voltage and current of the photovoltaic cell with which the primary stage power efficiency optimizer is in electrical communication as the output of the photovoltaic cell varies over time.

A further aspect of an embodiment provides a photovoltaic power generation system wherein at least one of primary stage power efficiency optimizers and/or at least one of the secondary stage power efficiency optimizers comprise a maximum point tracker and a DC/DC converter.

A further aspect of an embodiment provides a photovoltaic power generation system wherein the at least one of the primary stage power efficiency optimizer and the secondary stage power efficiency optimizer comprises control circuitry, a system-on-a-chip controller, or a microcontroller.

A further aspect of an embodiment provides a photovoltaic power generation system wherein at least some of the primary stage power efficiency optimizers comprise a bypass mechanism.

A further aspect of an embodiment provides a photovoltaic power generation system wherein at least some of the secondary stage power efficiency optimizers comprise a bypass mechanism.

A further aspect of an embodiment provides a photovoltaic power generation system wherein at least one of: (i) the primary stage power efficiency optimizers, and (ii) the secondary stage power efficiency optimizers, are powered by at least one corresponding secondary photovoltaic cell.

A further aspect of an embodiment provides a photovoltaic power generation system wherein one or more strings of photovoltaic cell modules are arranged on at least one solar panel.

A further aspect of an embodiment provides a photovoltaic power generation system further comprising a local control unit near the solar panel, the local control unit containing the at least one secondary stage power efficiency optimizer.

A further aspect of an embodiment provides a method for conversion of solar power to electrical power by a system comprising a plurality of strings of photovoltaic cells, the method comprising converting solar energy into electricity with the photovoltaic cells for at least one of the strings, simultaneously adjusting an output voltage and current of each photovoltaic cell of the string to reduce loss of output power of the string resulting from at least one of voltage and current differences amongst the photovoltaic cells of the string; and simultaneously adjusting an output voltage and current of each string to reduce loss of power of the system resulting from at least one of voltage and current differences amongst the plurality of strings.

A further aspect of an embodiment provides a method for conversion of solar power to electrical power by a system further comprising, for each photovoltaic cell of the at least one string, concentrating sunlight through a corresponding optical concentrator onto the photovoltaic cell.

A further aspect of an embodiment provides a method for conversion of solar power to electrical power by a system, wherein adjusting an output voltage and current of each photovoltaic cell comprises sensing an output current and an output voltage of the photovoltaic cell and locking one of the output current or output voltage of the photovoltaic cell to the maximum power point of the photovoltaic cell.

A further aspect of an embodiment provides a method for conversion of solar power to electrical power by a system wherein adjusting an output voltage and current of each string comprises sensing an output current and an output voltage of the string and locking one of the output current or output voltage of the string to the maximum power point of the string.

A further aspect of an embodiment provides a method for conversion of solar power to electrical power by a system further comprising converting the DC power from the strings to AC power.

Embodiments of the present invention may have one or more of the above-mentioned aspects, but do not necessarily comprise all of the above-mentioned aspects or objects described herein, whether express or implied. It will be understood by those skilled in the art that some aspects of the embodiments described herein may have resulted from attempting to attain objects implicitly or expressly described herein, but may not satisfy these express or implied objects, and may instead attain objects not specifically recited or implied herein.

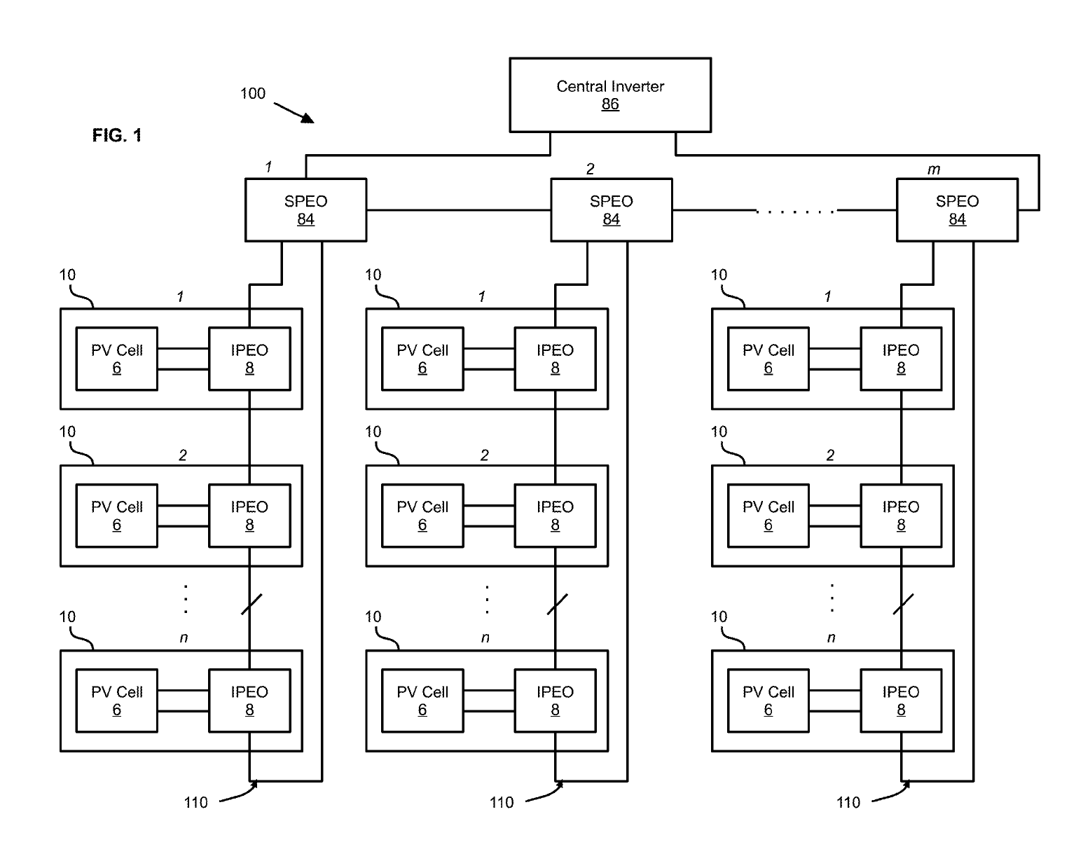

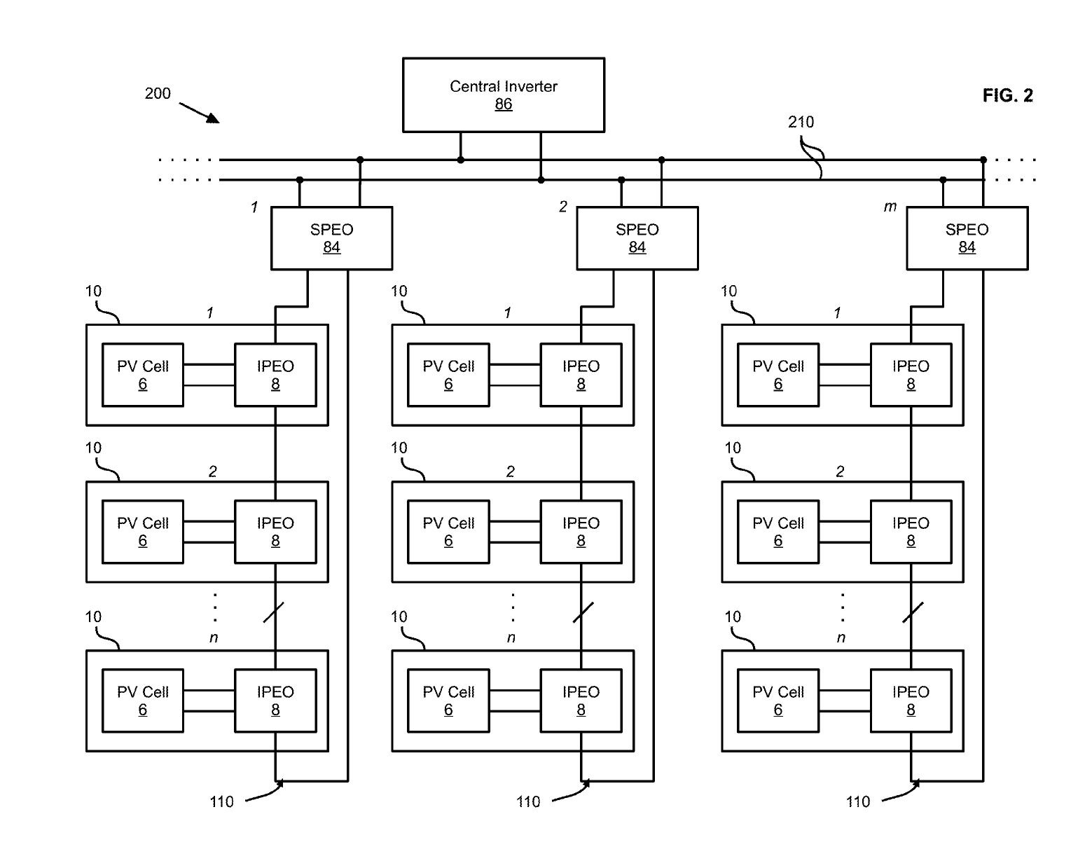

Examples of PV power generation systems 100, 200 that employ primary stage power efficiency optimizers and secondary stage power efficiency optimizers are illustrated in FIGS. 1 and 2. In these examples, the primary stage power efficiency optimizers are integrated power efficiency optimizers (IPEOs) 8 and the secondary stage power efficiency optimizers are string-level power efficiency optimizers (SPEOs) 84. The terms “primary stage power efficiency optimizer” and IPEO are used interchangeably herein even though the IPEO 8 is only an example of a primary stage power efficiency optimizer that may be used. Similarly, the terms “secondary stage power efficiency optimizer” and SPEO are used interchangeably herein even though the SPEO 84 is only an example of a secondary stage power efficiency optimizer that may be used. The PV power generation systems 100, 200 have m strings 110 of n integrated PV cell modules 3 connected to a central DC/AC inverter 86. The central inverter 86 converts the DC power output from the interconnected strings 110 to AC.

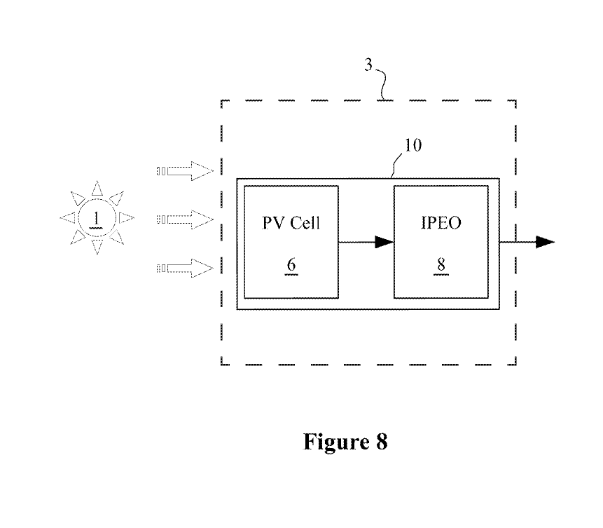

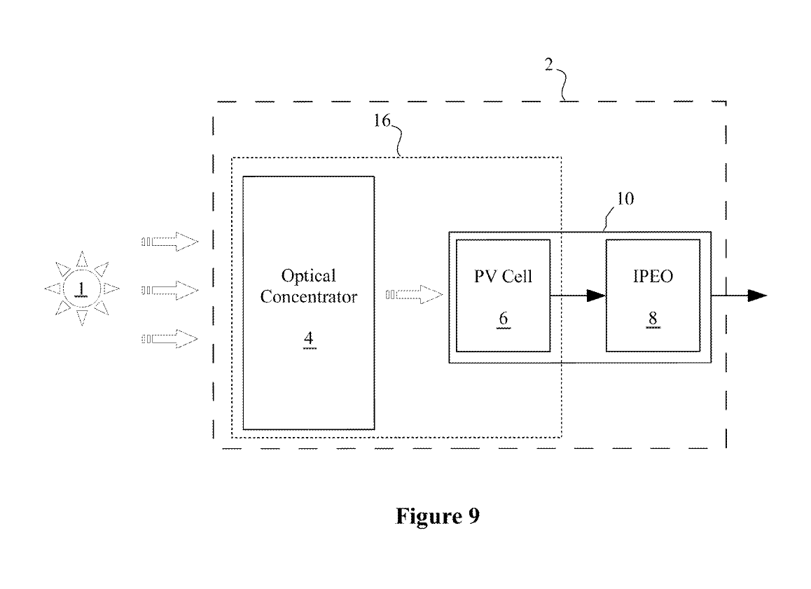

As illustrated in FIG. 8, each of the integrated PV cell modules 3 has a PV cell 6 integrated in a sunlight receiver assembly 10 with an IPEO 8 in electrical communication with the PV cell 6 to provide simultaneous adjustment of the output voltage and current of the PV cell 6 to reduce loss of output power of multiple PV cells 6 due to irregularities in the integrated PV cell modules. The integrated PV cell module 3 may, but need not, include an optical concentrator 4. Where the integrated PV cell module 3 includes an optical concentrator 4 as illustrated in FIG. 9, the integrated PV cell module 3 may be referred to as an integrated CPV module 2.

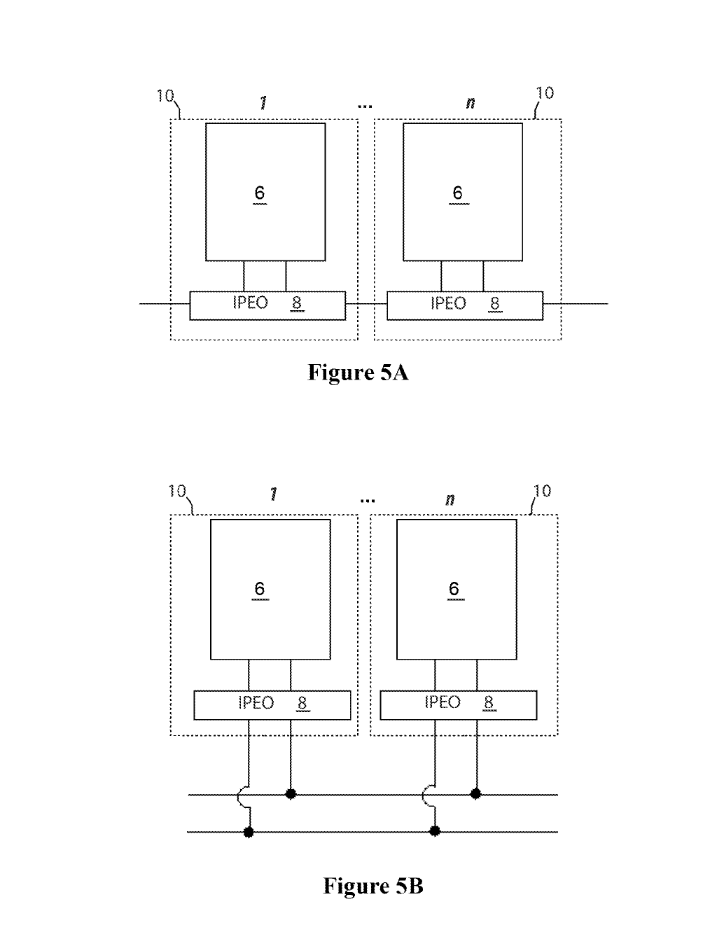

In the example illustrated in FIG. 1, the IPEOs 8 of the integrated PV cell modules 3 of each string 110 are connected in series (as shown in FIG. 5A) to an SPEO 84 and m SPEOs 84 are connected in series to the central inverter 86. In the example illustrated in FIG. 2, the IPEOs 8 of the integrated PV cell modules 3 of each string 110 is connected in series to an SPEO 84 and each SPEO 84 is connected in parallel to the central inverter 86. Alternatively, the IPEOs 8 of the integrated PV cell modules 3 of each string 110 can be connected in parallel (as shown in FIG. 5B) to an SPEO 84 and the SPEO 84 can be connected in series or in parallel to the central inverter 86. The IPEOs of the integrated PV cell modules 3 of each string 110 can also be connected to form a matrix as shown in FIG. 5C, where n IPEOs are connected in series to form a row 88 and p rows 88 are connected in parallel to the central inverter 86. While it is shown in FIGS. 1 and 2 that each string 110 has n receiver assemblies 10 and therefore n integrated PV cell modules 3, a string 110 can have a different number of integrated PV cell modules 3 from other strings 110 in the PV power generation system 100, 200.

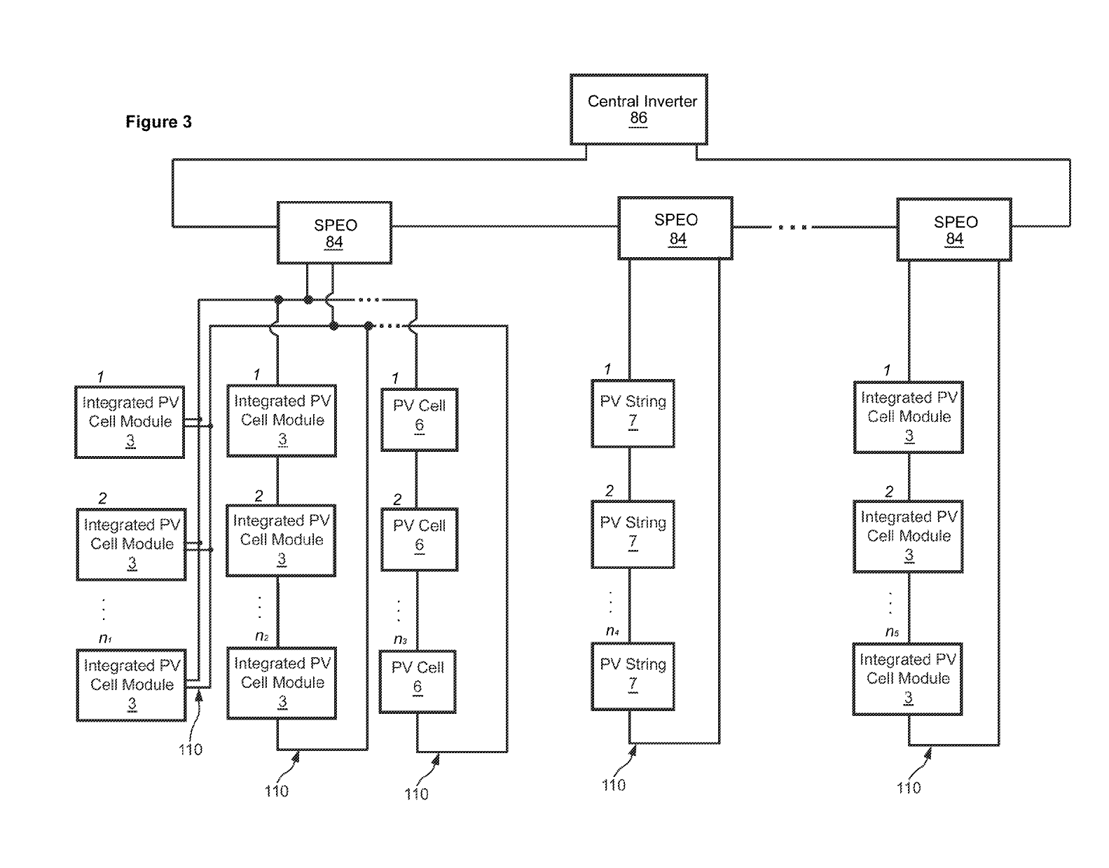

With reference to FIG. 3, multiple strings 110 may be connected to a single SPEO 84. Strings of integrated PV cell modules 3 containing n₁ modules 3 may be connected in parallel with other strings 110. Other strings may also include integrated PV cell modules 3, illustrated as 1 . . . n₂, or PV cells 6, illustrated as 1 . . . n₃, connected either in parallel or in series. While FIG. 3 includes three strings connected to the left SPEO 84, a single SPEO 84 may be connected to any number of strings 110. The single SPEO 84 may be connected either in series or in parallel with the strings 110 depending on the properties and operating characteristics of the PV cells, the integrated PV cell modules 3 and the SPEO 84.

Again with reference to FIG. 3, a number of PV strings 7, illustrated as 1 . . . n₄, may be connected in series with a single SPEO 84. Each PV string 7 may contain one or more PV cells or integrated PV cell modules 3. In such a circumstance, conventional PV cells without concentrating features may be efficiently integrated into CPV systems or vice versa.

A single SPEO 84 may be connected with a number of integrated PV cell modules 3, illustrated as 1 . . . n₅. As discussed earlier, the SPEOs 84 may be connected in series with a central inverter 86 as illustrated in FIG. 3 or in parallel.

The SPEOs can therefore facilitate use of a single central inverter 86 to convert the DC power collected from different types of strings and can reduce the number of inverters and conductors needed in a farm, thereby reducing the cost of the farm.

IPEOs 8 integrated within each of the integrated PV cell modules 3 can step up voltage for each string so that each string can operate at the highest voltage possible to reduce electrical losses and to allow use of smaller conductors within the strings 110. While the IPEOs 8 generally step up voltage, they can also step down voltage as needed.

Secondary stage power efficiency optimizers 84, such as SPEOs, can step up the voltage in addition to or instead of the IPEOs 8. SPEOs 84 can be used to step up the voltage if selected IPEOs 8 have low operating voltage as lower operating voltage IPEOs 8 are generally less costly than IPEOs 8 having a higher operating voltage. The secondary stage power efficiency optimizers 84 may alternatively step down the voltage, for example, to stay within optimal voltage limits of the central inverter 86.

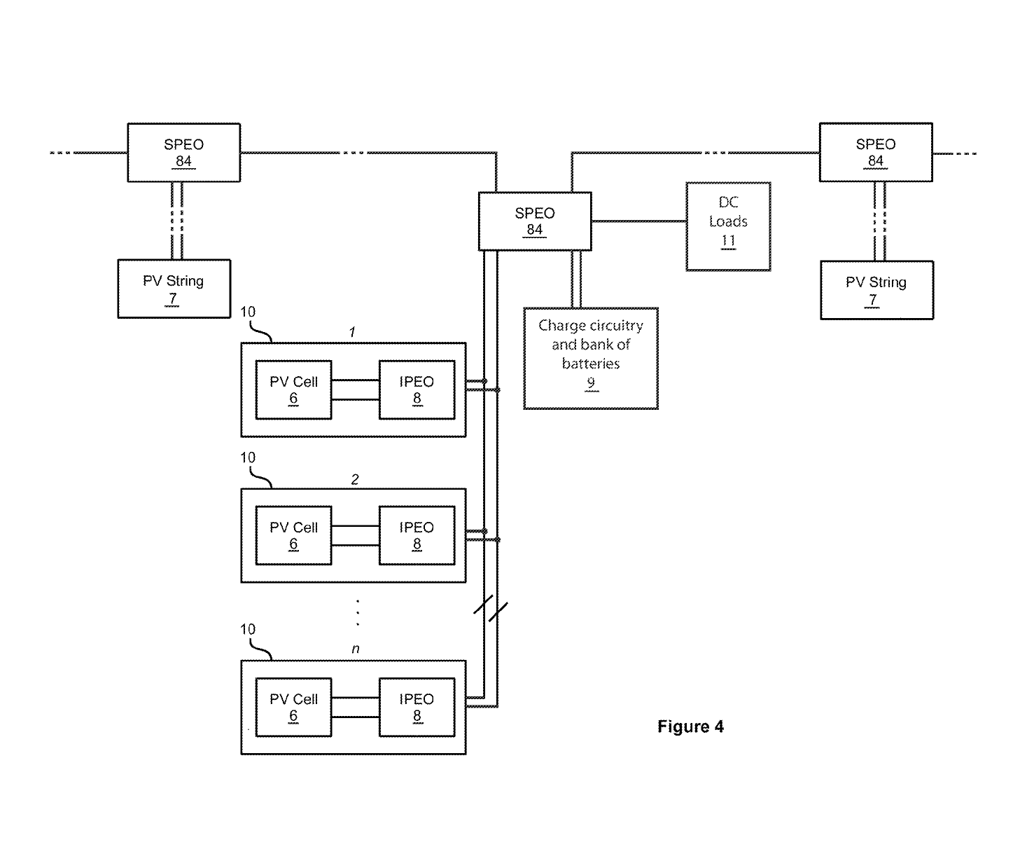

With reference to FIG. 4, in an embodiment, charge circuitry and batteries 9 may be connected to one or more SPEOs 84. In this way, power from the string or strings through the SPEO 84 may be used to charge the bank of batteries using the charging circuitry. When the string or strings is not generating power, such as at night or when the PV cells are shaded or otherwise obscured, power from the batteries, through the SPEO 84 may be used to power the DC loads 11 connected to the SPEO 84. These DC loads may include an inverter 86 and/or other electrical devices of the PV power generating system.

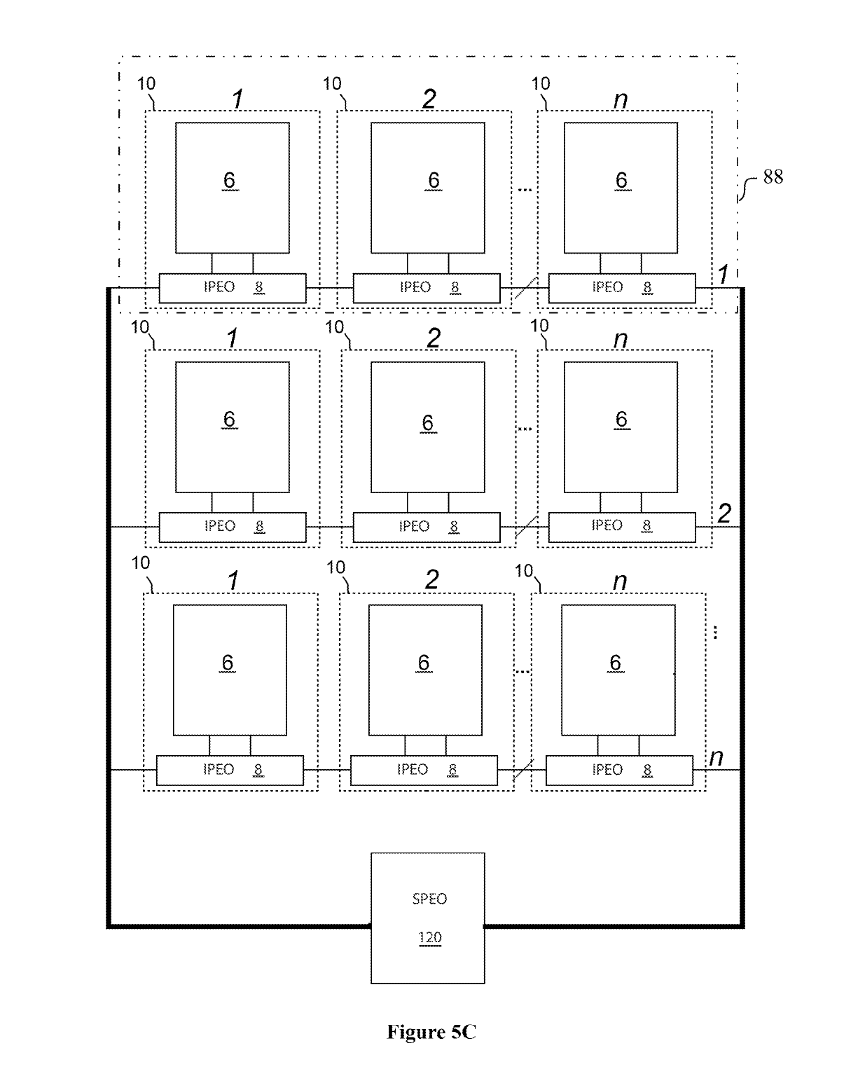

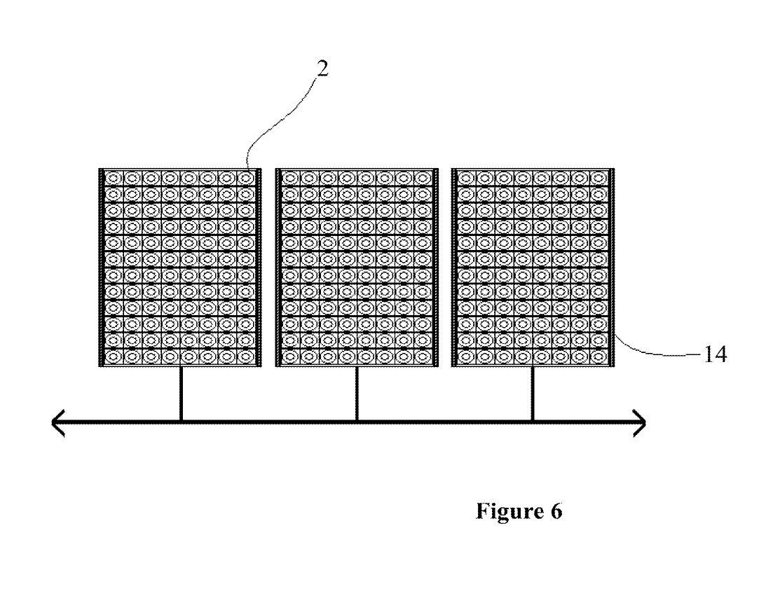

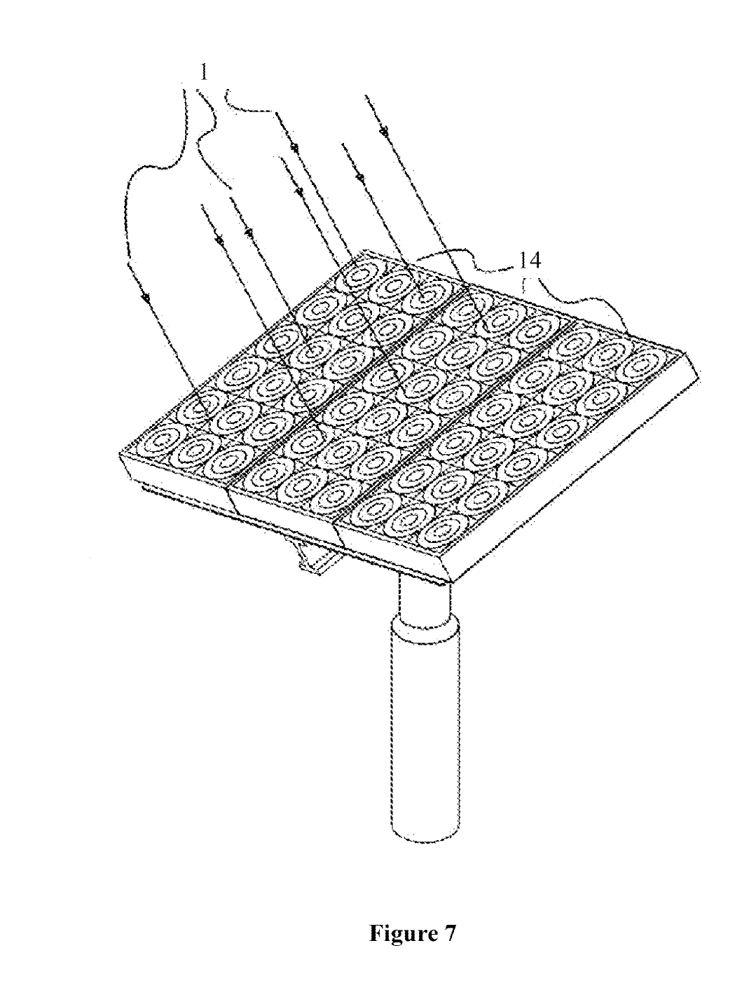

The strings 110 of integrated PV cell modules 3 can be arranged on one or more solar panels 14 as shown in FIGS. 6 and 7. Each solar panel 14 may thus support one or more strings 110 of integrated PV cell modules 3 and one or more secondary stage power efficiency optimizers 84. As shown in FIG. 7, the solar panel 14 can be attached to a solar tracking system of one or more axes. Each solar panel 14 may work alone, or in conjunction with several other solar panels 14 in an array, as shown in FIG. 6, in a solar farm or other environments. The solar panels 14 in the array can include one or both of integrated CPV modules 2 and non-concentrating PV cell modules and may comprise any number of integrated PV modules 3.

The secondary stage power efficiency optimizers 84 can be located on the solar panels 14 and therefore near the string or stings 110 with which they are associated. Alternatively, the SPEOs 84 can be located near the solar panel 14 on which the string or strings 110 with which they associated are found, such as in a local control unit that controls one or more solar panels. The local control unit may therefore include SPEOs for a single panel or for several panels. The location of the secondary stage power efficiency optimizers 84 may be determined by the cost of installing them close to the PV cells on the panels as compared to installing them in a common location further from the PV cells.

An SPEO 84 is a power conditioner such as a DC-DC converter designed to track the Maximum Power Point (MPP) of one or more PV strings. The SPEO 84 can therefore comprise a Maximum Power Point Tracker (MPPT). In an embodiment, the SPEO may be embodied in control circuitry or a system-on-a-chip (SoC) controller to implement the MPPT. The SPEO may be implemented in a similar manner as the IPEO described below.

FIG. 9 illustrates an integrated CPV module 2 of the type that may be used with the embodiments described herein. The integrated CPV module 2 generally comprises an optical module 16, which in turn comprises a sunlight optical concentrator 4 and a PV cell 6 optically coupled to the optical concentrator 4 to receive concentrated sunlight therefrom.

Optical concentrators generally comprise one or more optical elements for the collection and concentration of light, such as focusing elements including lenses and mirrors, light- or waveguides, and other optically concentrative devices retained in a fixed spatial position relative to the PV cell and optically coupled to an active surface of the PV cell. Examples of optical elements include Winston cones, Fresnel lenses, a combination of a lens and secondary optics, total internal reflection waveguides, luminescent solar concentrators and mirrors.

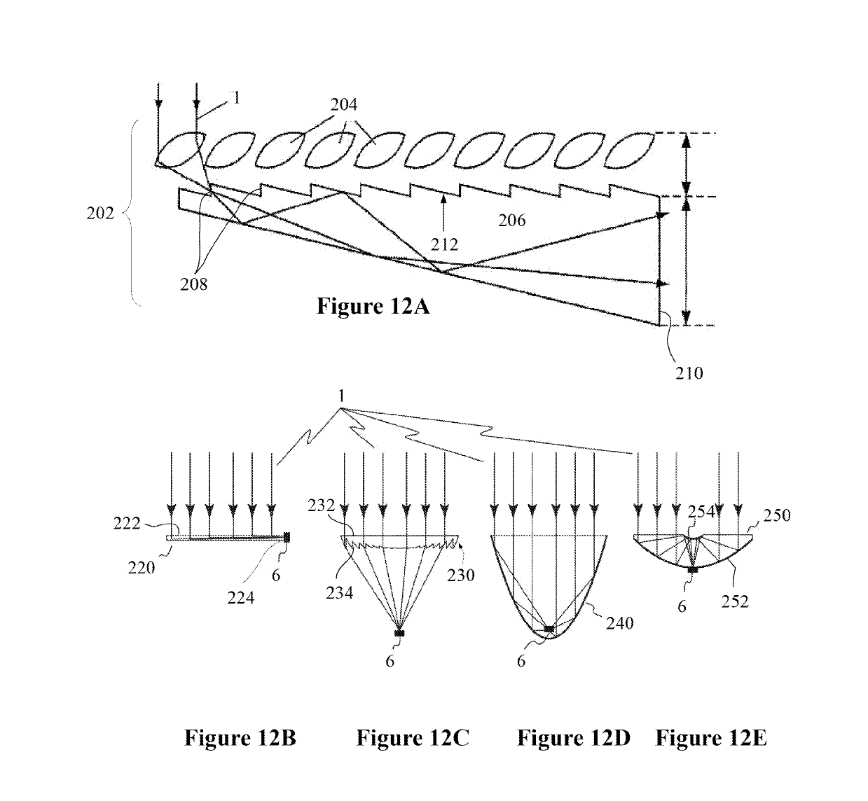

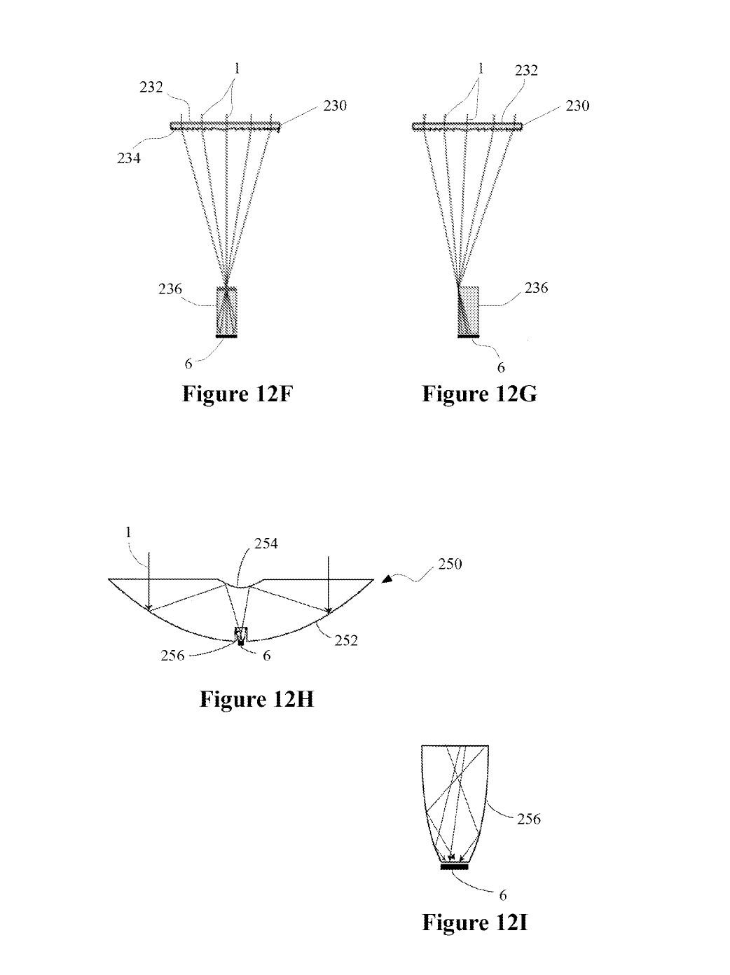

The optical concentrator of the integrated CPV module 2 may comprise a single optical element or several optical elements for collecting, concentrating and redirecting incident light on the PV cell 6. Examples of single-optic assemblies are illustrated in FIGS. 12B-12D. The optical concentrator 220 of FIG. 12B comprises a total internal reflection waveguide that accepts light incident upon one or more surfaces 222 of the waveguide and guides the light by total internal reflection to a PV cell 6 at an exit surface 224. The optical concentrator 230 of FIG. 12C comprises a Fresnel lens which redirects light incident upon a first surface 232 toward a PV cell 6 maintained in fixed relation to a second surface 234 of the Fresnel lens 230 opposite the first surface 232. The optical concentrator 240 of FIG. 12D is a parabolic reflector in which a PV cell is maintained at the focal point of the reflector.

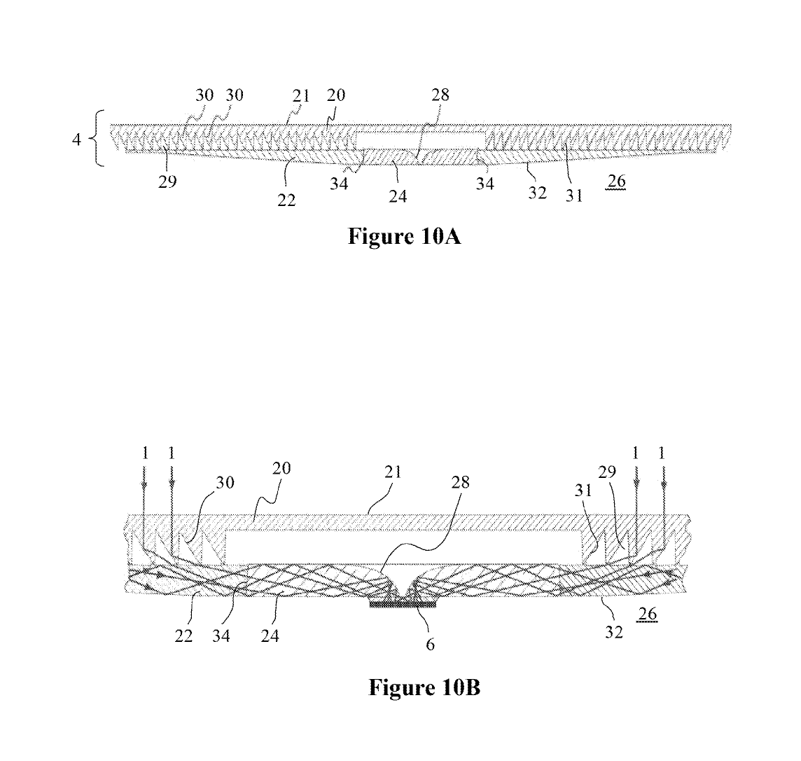

Embodiments of multiple-optic assemblies are described below with reference to FIGS. 10A, 10B, 11, 12E-12I, 13A and 13B and in United States Patent Application Publication No. 2008/0271776, filed May 1, 2008, titled “Light-Guide Solar Panel And Method Of Fabrication Thereof”, United States Patent Application Publication No. 2011/0011449, filed Feb. 12, 2010, titled “Light-Guide Solar Panel And Method Of Fabrication Thereof”, U.S. Provisional Patent Application No. 61/298,460, filed Jan. 26, 2010, titled “Stimulated Emission Luminescent Light-Guide Solar Concentrators”, the entireties of which are incorporated herein by reference.

The sunlight concentration unit 250 of FIG. 12E comprises a primary optic 252 and a secondary optic 254. The primary optic 252 may be a dome-shaped reflector that reflects incident light toward a secondary optic 254. In turn, the secondary optic 254 reflects the light toward a PV cell 6 mounted to the base of the dome.

Optical concentrators 4 comprising a focusing element that focuses the sunlight into a light beam, such as those in the examples of FIGS. 12F, 12G and 12H, may further comprise a relatively small light guide 236 and 256. The light guide 236 and 256 is located in the focal plane of the focusing element and is optically coupled to the focusing element 230, 250 to further guide the light toward the PV cell 6 as shown in FIGS. 12F, 12G and 12I.

Referring to FIGS. 10A and 10B, the optical concentrator 4 may include a primary optic, which may comprise a focusing element or light insertion stage 20 and an optical waveguide stage 22, and a secondary optic 24. The light insertion stage 20 and the optical waveguide stage 22 may each be made of any suitable optically transmissive material. Examples of suitable materials can include any type of polymer or acrylic glass such as poly(methyl-methacrylate) (PMMA), which has a refractive index of about 1.49 for the visible part of the optical spectrum.

The light insertion stage 20 receives sunlight 1 impinging a surface 21 of the light insertion stage 20, and guides the sunlight 1 toward optical elements such as reflectors 30, which preferably directs the incident sunlight by total internal reflection into the optical waveguide or light guide stage 22. The reflectors 30 may be defined by interfaces or boundaries 29 between the optically transmissive material of the light insertion stage 20 and the second medium 31 adjacent each boundary 29. The second medium 31 may comprise air or any suitable gas, although other materials of suitable refractive index may be selected. The angle of the boundaries 29 with respect to impinging sunlight 1 and the ratio of the refractive index of the optically transmissive material of the light insertion stage 20 to the refractive index of the second medium 31 may be chosen such that the impinging sunlight 1 undergoes substantially total internal reflection or total internal reflection. The angle of the boundaries 29 with respect to the impinging sunlight 1 may range from the critical angle to 90°, as measured from a surface normal to the boundary 29. For example, for a PMMA-air interface, the angle may range from about 42.5° to 90°. The reflectors 30 thus defined may be shaped like parabolic reflectors, but may also have any suitable shape.

As illustrated in FIG. 10B, the sunlight then propagates in the optical waveguide stage 22 towards a boundary 32, angled such that the sunlight 1 impinging thereon again undergoes total internal reflection, due to the further medium 26 adjacent the boundary 32 of the optical waveguide stage 22. The sunlight 1 then propagates toward a surface adjacent the light insertion stage 20 at which it again undergoes total internal reflection or substantially total internal reflection. The sunlight 1 continues to propagate by successive internal reflections through the optical waveguide stage 22 toward an output interface 34 positioned “downstream” from the sunlight's entry point into the optical waveguide stage 22. In an embodiment of the optical concentrator 4 shaped in a substantially square or circular form, with substantially circular concentric reflectors 30 disposed throughout the light insertion stage 20, the output interface 34 may be defined as an aperture at the centre of the concentrator 4.

The sunlight then exits the optical waveguide stage 22 at the output interface 34 and enters the secondary optic 24, which is a second focusing element 24 and is in optical communication with the output interface 34 and directs and focuses the sunlight onto an active surface of a PV cell (not shown in FIG. 10A). The secondary optic may comprise a parabolic coupling mirror 28 to direct incident light towards the PV cell. The PV cell may be aligned with the secondary optic 24 so as to receive the focused sunlight at or near a center point of the cell. The secondary optic 24 may also provide thermal insulation between the optical waveguide stage 22 and the PV cell 6.

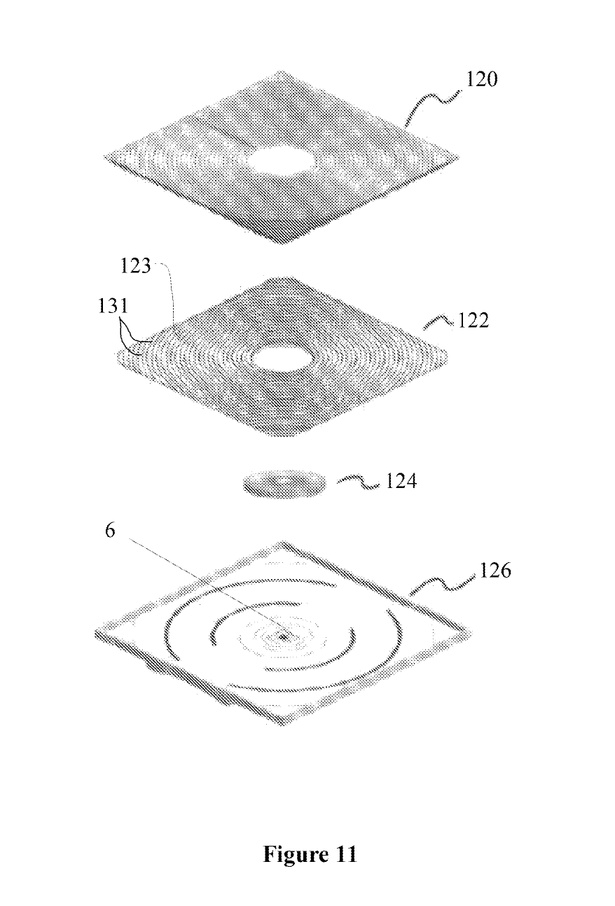

In the embodiment illustrated in FIG. 11, a light insertion stage 120 and a optical waveguide stage 122 that are similar to the light insertion stage 20 and optical waveguide 22 of FIG. 10A are mountable with the secondary optic 124 that is similar to secondary optic 24 of FIGS. 10A and 10B, in a tray 126, which provides support to the substantially planar stages 120, 122 as well as to the secondary optic 124 and the PV cell 6. The second medium 131 may be the material of the optical waveguide stage 122 and may be integral to the optical waveguide stage 122, forming ridges on the surface 123 of the optical waveguide stage 122 adjacent the insertion stage 120. The light insertion stage 120, the optical waveguide stage 122 and the secondary optic 124 are otherwise as described above in reference to FIGS. 10A and 10B. The PV cell 6 may be fixedly mounted to the tray 126 so as to maintain its alignment with the secondary optic 124. The tray 126 may be formed of a similar optical transmissive medium as the stages 120, 122, and may include means for mounting on a solar panel.

In another embodiment, the optical concentrator 202 in FIG. 12A described in United States Patent Application Publication No. 2008/0271776, filed May 1, 2008, comprises a series of lenses 204 disposed in a fixed relation to a waveguide 206. Incident light 1 is focused by the lenses 204 onto interfaces 208 provided at a surface 212 of the waveguide 206, and are redirected through total internal reflection towards an exit interface 210, and optionally propagated through further optics before focusing and concentrating the light 1 on a PV cell (not shown).

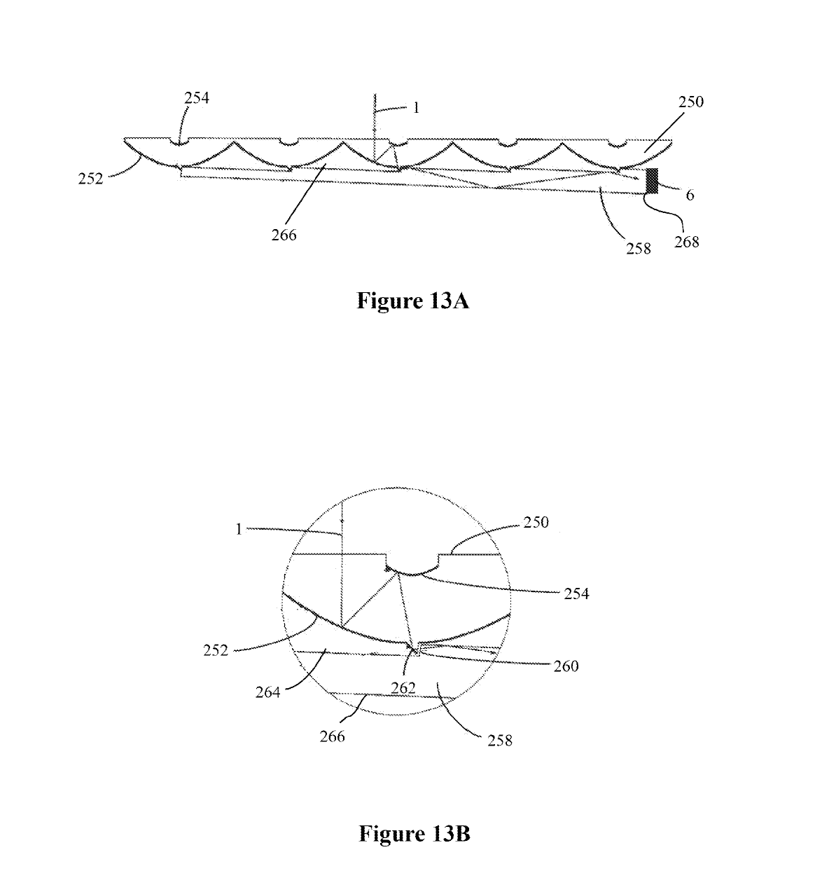

Alternatively, as illustrated in FIGS. 13A and 13B, a plurality of sunlight concentration units 250 may be provided as a light insertion stage, wherein instead of having a PV cell mounted to the base of the dome, a reflector 262 is provided to direct light into a light guide 258 at a light insertion surface 260 of the light guide 258. The sunlight 1 then propagates in the light guide 258 towards a surface 264 facing the light insertion stage, angled such that the sunlight 1 impinging thereon again undergoes total internal reflection. The sunlight 1 then propagates toward a boundary 266 at which it again undergoes total internal reflection or substantially total internal reflection. The sunlight 1 continues to propagate by successive internal reflections through the light guide 258 toward an output surface 268 positioned “downstream” from the sunlight's entry point into the light guide 258. Concentrated sunlight is thus directed onto a PV cell 6 positioned at the output surface 268 of the light guide 258.

Focusing elements may thus be refractive optical elements as in the examples of FIGS. 10A, 10B, 11, 12A, 12C and 12F or may be reflective optical elements such as in the examples of FIGS. 12D, 12E, 12H, 13A and 13B.

As will be appreciated by those skilled in the art, the optical concentrator used may be of any known and practical type. Other examples of types of optical concentrators 4 that may be used include Winston cones and luminescent solar concentrators.

The degree of concentration to be achieved by the optical concentrator 4 is selected based on a variety of factors known in the art. The degree of concentration may be in a low range (e.g., 2-20 suns), a medium range (e.g., 20-100 suns) or a high range (e.g., 100 suns and higher).

In many of the foregoing embodiments, the PV cell 6 may be integrated with the optical concentrator 4 to provide an optical module 16 that is easy to assemble, as in the example of FIG. 11. The PV cell 6 may be a multi junction cell (such as a double-junction or triple junction cell) to improve absorption of incident sunlight across a range of frequencies, although a single-junction cell may also be used. The PV cell 6 may have a single or multiple active surfaces. In some embodiments, positive and negative contacts on the solar cell are electrically connected to conductor traces by jumper wires, as described in further detail below.

The efficiency of an optical module 16 such as that described above, referenced in FIG. 6, is generally determined by the efficiencies of the optical concentrator 4 and the PV cell 6. Generally, the PV cell 6 is characterized by a photovoltaic efficiency that combines a quantum efficiency and an electrical efficiency. The optical concentrator 4 is characterized by an optical efficiency.

The efficiency of both components is dependent on both internal and external factors, and the efficiency of the optical module 16 as a whole may be affected by still further factors. In the case of the optical concentrator, design, manufacturing and material errors, and operating and environmental conditions may result in the degradation of the concentrator and of the module as a whole. For example, point defects in the one or more optical elements of the concentrator, which may be introduced during manufacture, will reduce the efficiency of the concentrator. Each optical element therefore has at least a given optical efficiency, which may comprise a measurable difference between an amount of sunlight input at the optical element and an amount of sunlight output from the optical element. In an embodiment of a multi-optic concentrator comprising one or more focusing elements and one or more light guides, each focusing element will have a first optical efficiency and each light guide will have a second optical efficiency. In an optic concentrator having a single optic element, a single optical efficiency may be associated therewith.

Angular or lateral misalignments of the optical elements, which may be introduced during manufacture, shipping, or even in the field, will also affect the optical efficiency of the concentrator as a whole. Even without external influences, transmission losses may be suffered due to factors such as mirror reflectivity, absorption, and Fresnel reflection. In the case of a multiple-optic concentrator 4, the misalignments of the optical elements and other factors contribute to a third optical efficiency of the optical concentrator 4.

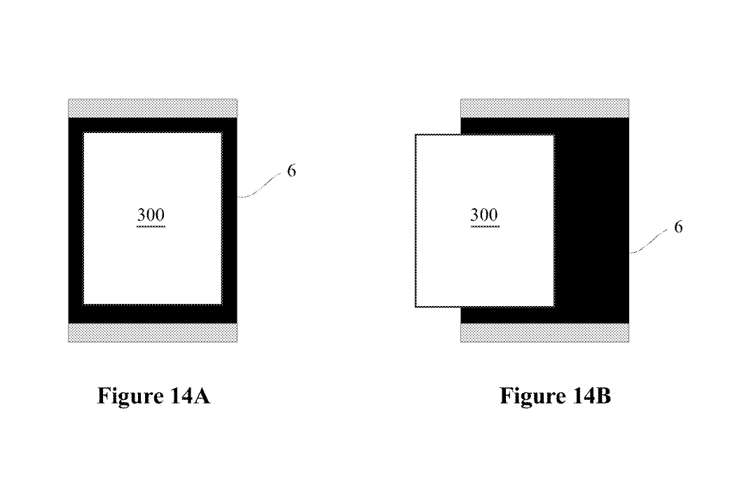

Within the optical module 16 itself, misalignment between the concentrator 4 and the PV cell 6 may result in misdirection of the focused light 300 on the PV cell 6 away from the most responsive central region of the PV cell 6 (as shown in FIGS. 12F and 14A) and towards an edge, as illustrated in FIGS. 12G and 14B. Such misalignment between the concentrator 4 and the PV cell 6 may also affect the third optical efficiency of a multiple-optic concentrator 4, or introduce a further optical efficiency of a single-optic concentrator 4. Misdirection may also be introduced where a solar tracking system used with the optical module 16 fails. Further, with regard to all components, aging and environmental conditions such as dust, fogging, and snow may generally adversely affect the component materials and lead to performance degradation over time.

Design, manufacturing, material errors related to the focusing elements and the waveguides that determine the optical efficiency of each of them may be compounded and may contribute to the errors of the optical concentrator 4. The second optical efficiency of a single-optic concentrator 4 may therefore be dependent on the first optical efficiency. Similarly, the third optical efficiency of a multi-optic concentrator 4 may be dependent on the first optical efficiencies and/or the second optical efficiencies of its constituent optical elements (which in the embodiment described above are focusing elements and light guides).

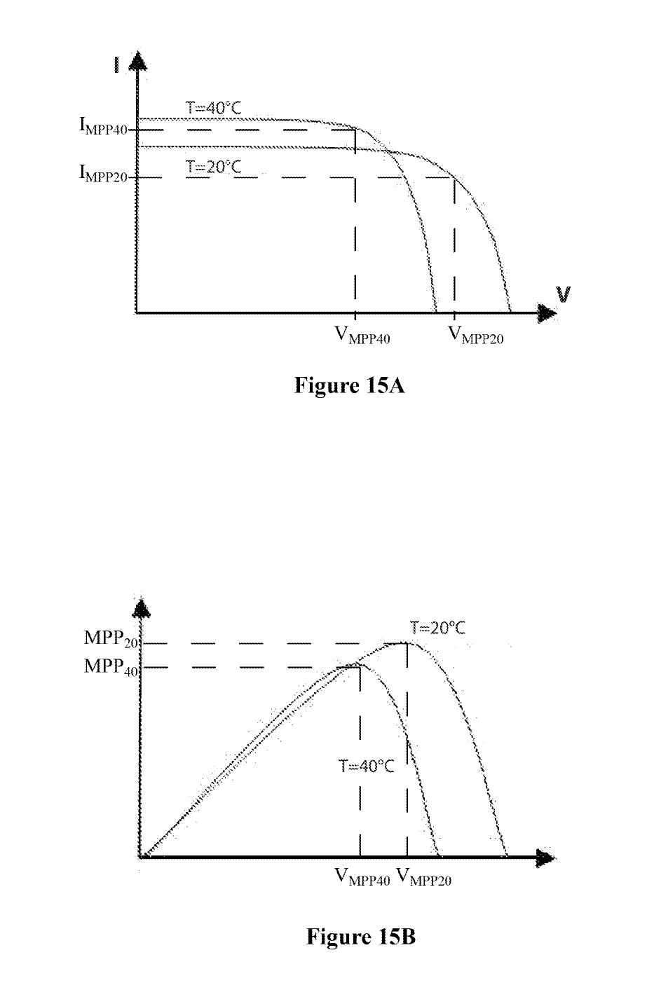

Further, variations in the manufacture and performance of the PV cell 6 itself may adversely affect efficiency. FIGS. 15A and 15B illustrate how the output current-output voltage characteristic (I-V curve) and output power-output voltage characteristic (P-V curve) of a solar cell, respectively, may vary at different operating temperatures. It is known that PV cells each have their own optimum operating point, called the maximum power point (MPP=I_{MPP}·V_{MPP}), that is highly dependent on the temperature and incident light on the PV cell and varies with age. Assemblies of PV cells also have an MPP that is dependent on the MPPs of its constituent PV cells.

In summary, numerous factors, both internal and environmental may adversely affect the overall efficiency of any PV cell module and may create a range of optical efficiencies among integrated PV cell modules 3 assembled in a string 110, a solar panel 14 or an array of solar panels. If the efficiency of integrated PV cell modules 3 within a solar panel 14 is not matched, the performance of the panel or array will be downgraded to the level of the lowest performing optical module. While some of these factors are controllable or at least manageable through binning and sorting at the manufacturing stage as mentioned above, there is still the possibility that further mismatches will be introduced during the shipping or installation process, or even during field use, where further binning or sorting may not be practical. Even the performance of a string or array of initially well-matched modules may be degraded due to variations or defects introduced after manufacture. Therefore, the efficiency of the optical elements generally varies over time.

To address at least some of these possible deficiencies, power conditioners such as DC-DC converters may be designed to track the MPP of a solar panel or string of PV cells. Such tools are known as Maximum Power Point Trackers (MPPTs). Power conditioners including MPPTs are typically located in the connection or junction box of the solar panel. Finding power conditioners such as MPPTs or inverters that can match varying output power from solar panels is extremely difficult, time consuming and costly; in some cases there may not be means available to convert such irregular power levels. In the case of PV cell mismatch, the output power will differ greatly amongst solar panels, thus requiring different power conditioners to match the output of each individual solar panel or MPPT.

Thus, in an embodiment of the integrated PV cell module 3, 2 as shown in FIG. 9 or 8, a receiver assembly 10 is provided with both the PV cell 6 and an IPEO 8 for providing, simultaneously, adjustment of the output voltage and current of the PV cell to reduce loss of output power of multiple PV cells resulting from differences amongst PV cell modules 3, 2 and power conversion of the PV cell output power. The IPEO 8 may therefore lock the output of the optical module to a constant voltage and/or constant current—the MPP voltage, V_{MPP}, and/or MPP current, I_{MPP}—thereby substantially reducing or eliminating undesirable effects of variations in the optical efficiency and/or photovoltaic efficiency of the concentrator 4 or PV cell 6, on a cell-by-cell basis. By providing PV cell-level optimization in this manner, the impact of variations between individual optical modules 16 in panels, strings 110 or arrays comprising multiple modules 16 caused by pre- or post-manufacturing, shipping, installation or field use incidents will be reduced, thereby improving the overall performance of the panels, strings or arrays.

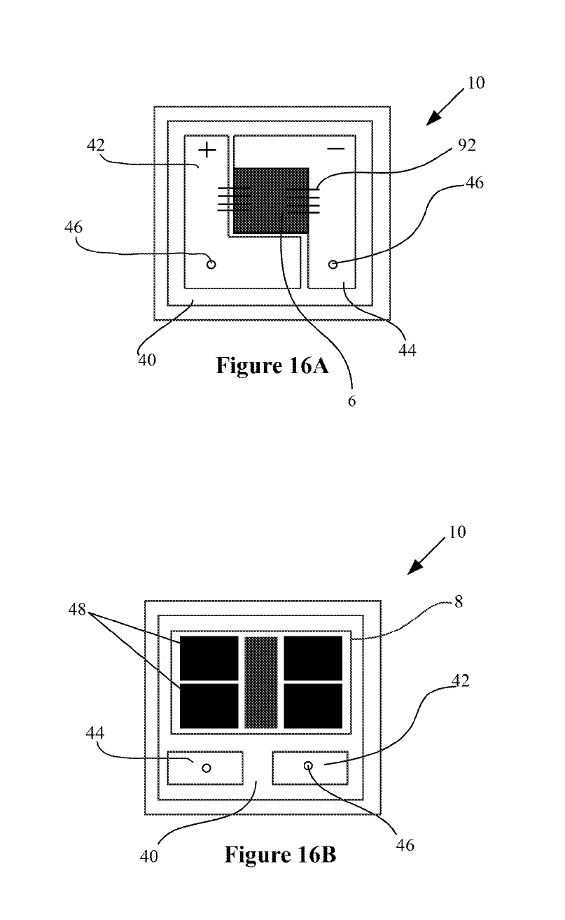

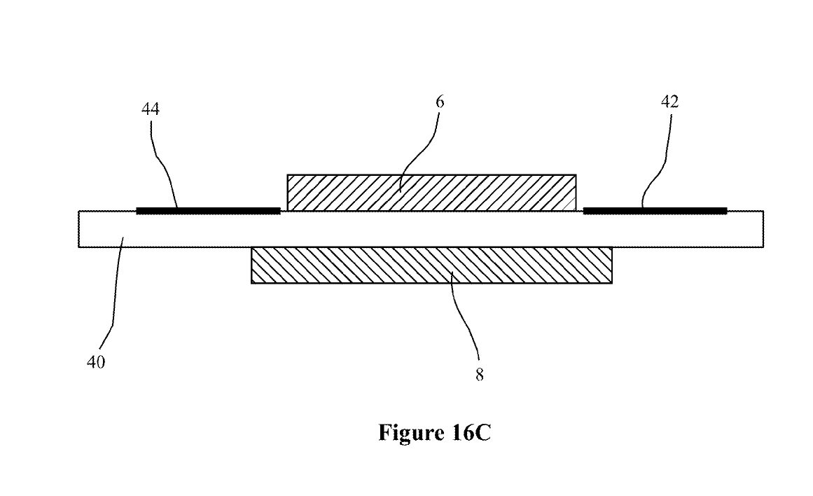

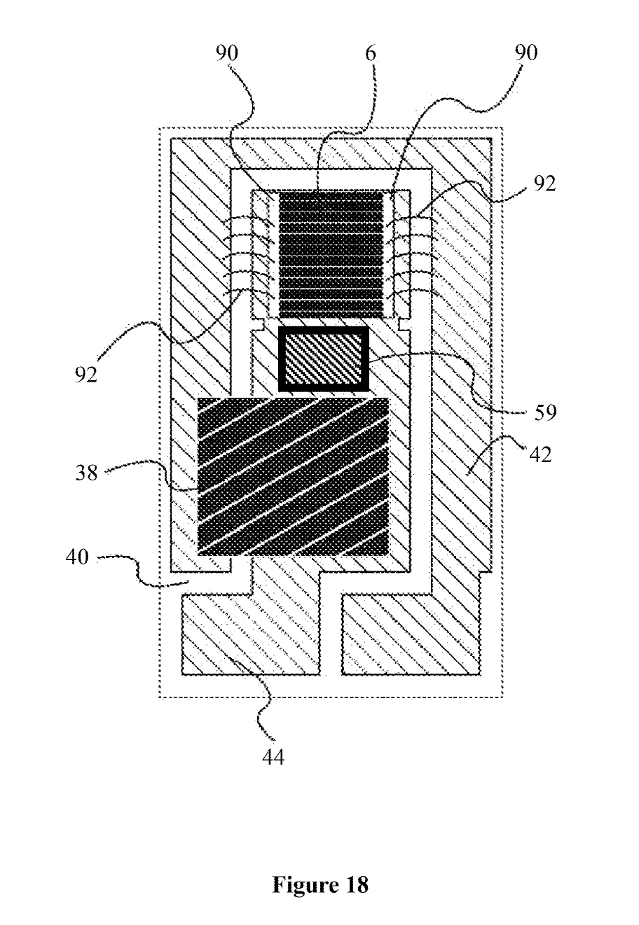

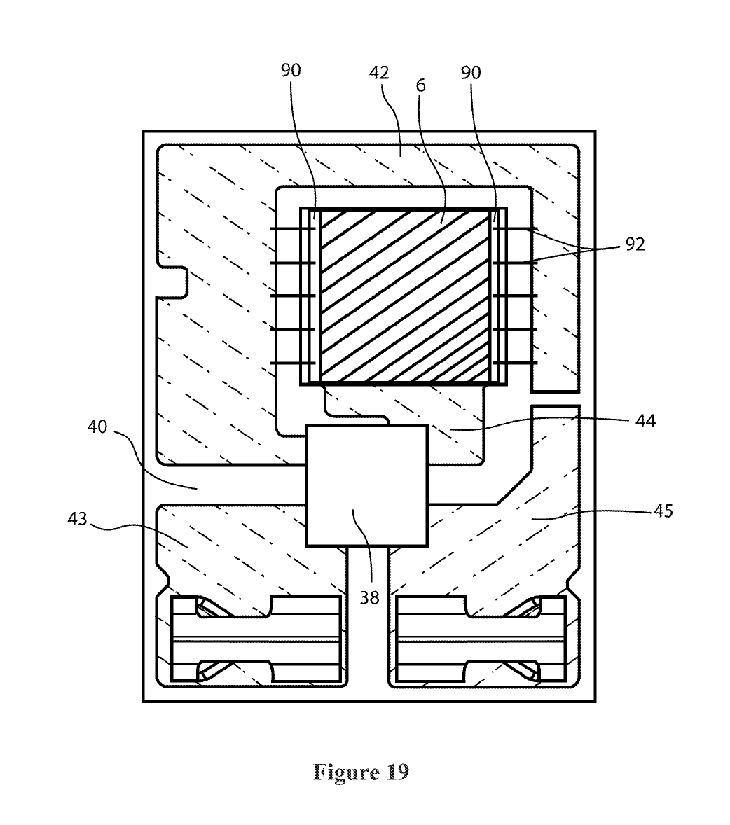

The receiver assembly 10 may be compactly and conveniently provided in a single integrated assembly. Referring to FIG. 16A, the receiver assembly 10 of an integrated CPV module 2 can be provided on a printed circuit board. In one embodiment, a PV cell 6 is affixed to a substrate 40 of the circuit board and electrically connected at its positive and negative contacts 90 (shown in FIGS. 18 and 19) by jumper wires 92 to positive and negative conductor traces 42, 44 printed on the substrate 40. The substrate 40 also supports the IPEO 8 which is in electrical communication with the PV cell 6. The receiver assembly 10 may also have vias 46. In this form, the receiver assembly 10 may be supported, for example, in the tray 126 of the optical module illustrated in FIG. 11, or mounted in relation to the various concentrators shown in FIGS. 12A through 12H.

The IPEO 8 can thus provide MPPT and power conversion for a single PV cell 6 of the same receiver assembly 10 on which the IPEO 8 is provided. In one embodiment, the IPEO 8 comprises control circuitry or a system-on-a-chip (SoC) controller to implement MPPT. In the embodiment of FIGS. 16A-16C, the PV cell 6 may be affixed to a first face of the substrate 40 and the IPEO 8 may be affixed to a second face of the substrate 40 opposite the face on which the PV cell 6 is mounted. In this embodiment, the IPEO 8 may comprise dedicated control circuitry implemented with several integrated circuit (IC) chips 48 and/or passive components such as heat sinks (not shown) to provide a robust controller. This embodiment also provides two vias 46; one via 46 through each of the conductor traces 42, 44.

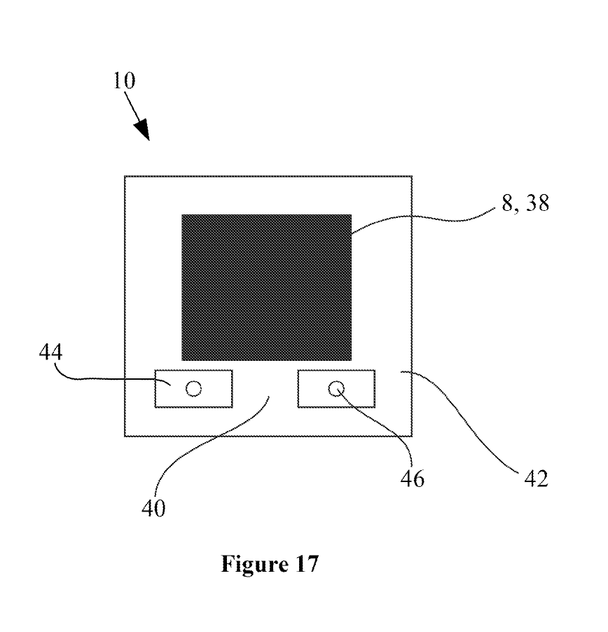

In an alternate embodiment shown in FIG. 17, the receiver assembly 10 is substantially similar to that shown in FIGS. 16A and 16B, except that the IPEO 8 comprises a single SoC 38 and may also comprise passive components (not shown). As an example, the SoC 38 can be a microcontroller. Use of an SoC 38 may reduce cost and facilitate manufacture of the integrated PV cell module 3.

In yet other embodiments of an integrated CPV module 2 shown in FIGS. 18 and 19, the PV cell 6 and the SoC 38 are both affixed to the first surface of the substrate 40.

In embodiments with bypass mechanisms, such as one or more bypass diodes 59 or bypass field-effect transistors (FETs), for serial connection of integrated CPV modules, the bypass controller 58 controls the bypass diodes 59. A bypass diode 59 may be enabled when the optical module 16 produces too little power to be converted. The bypass diodes 59 may be implemented as separate components from the SoC 38 as in FIG. 18, or may be incorporated into the SoC 38, as in FIGS. 17, 18, 19 and 21A/21B.

In other embodiments, such as that shown in FIG. 18, the IPEO 8 may be mounted on a separate printed circuit board 41 that forms part of the receiver assembly 10. The IPEO 8 is in electrical communication with the PV cell 6 via leads 47.

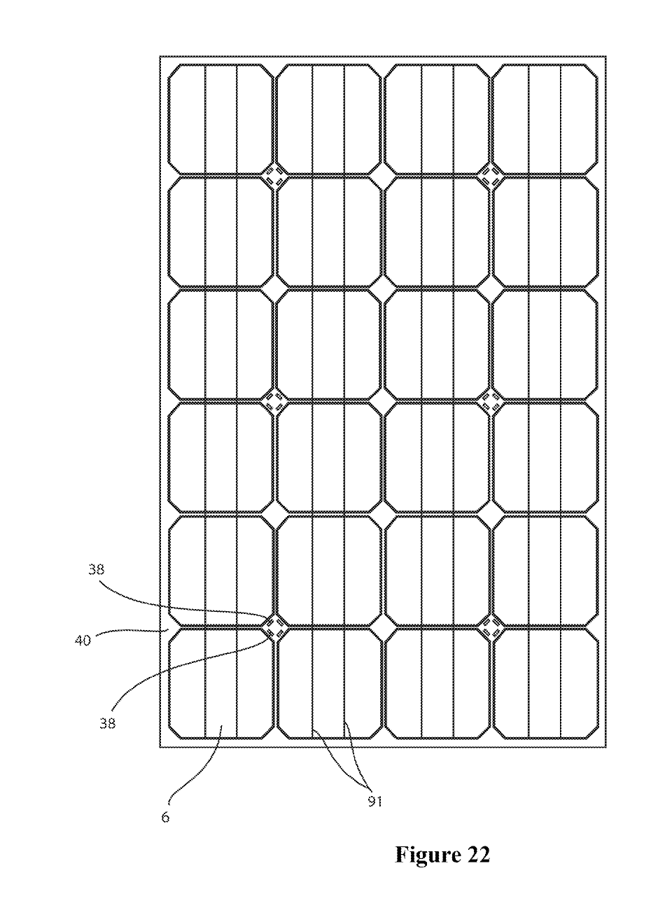

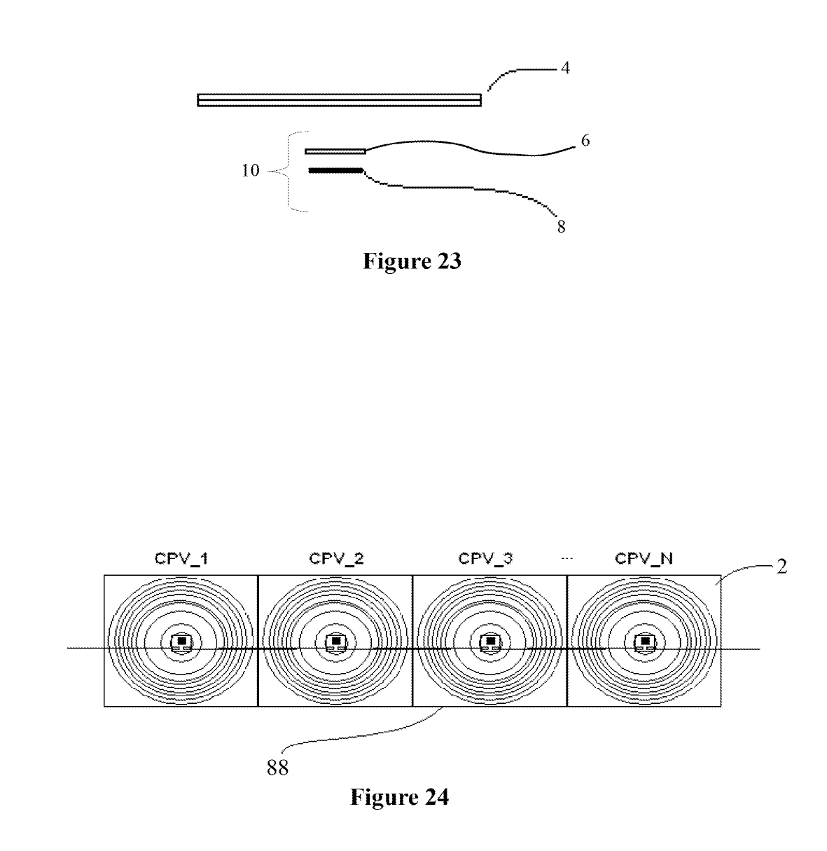

The receiver assemblies 10 of one or more strings 110 and therefore a plurality of PV cells and their corresponding SoCs 38, particularly in non-concentrating embodiments of integrated PV cell modules 3, can share a substrate 40 and thereby form a solar panel 14, as shown in FIG. 22. The PV cells 6 and SoCs 38 can be affixed to a first face as shown in FIG. 22, or the PV cells 6 can be affixed to the first surface while the SoCs 38 are affixed to a second face (not shown). Similarly, passive components (not shown) can be affixed to the first face or the second face. The SoCs 38 are in electrical communication with bus bars 91.

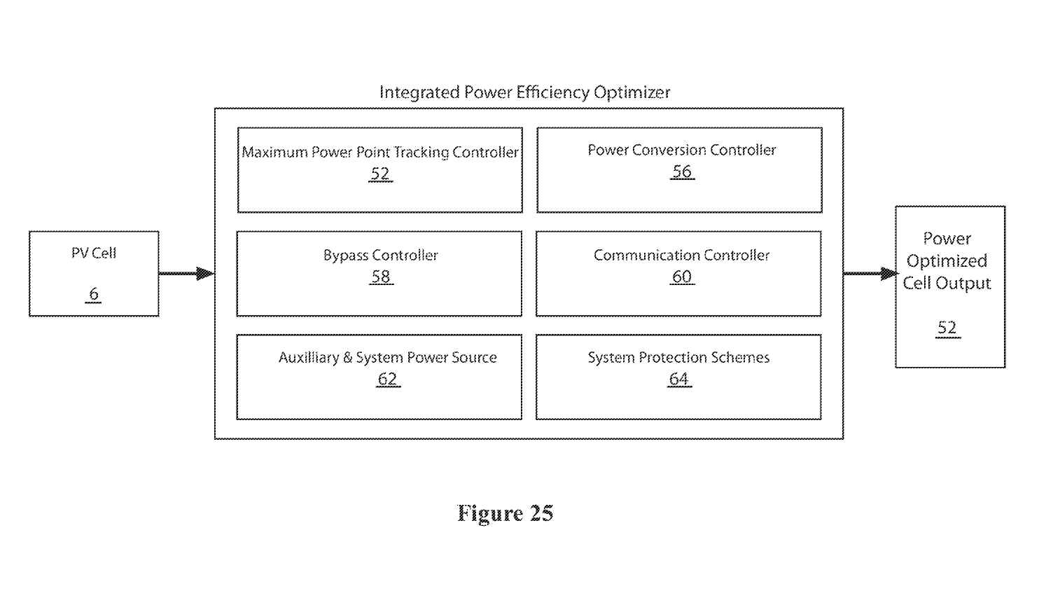

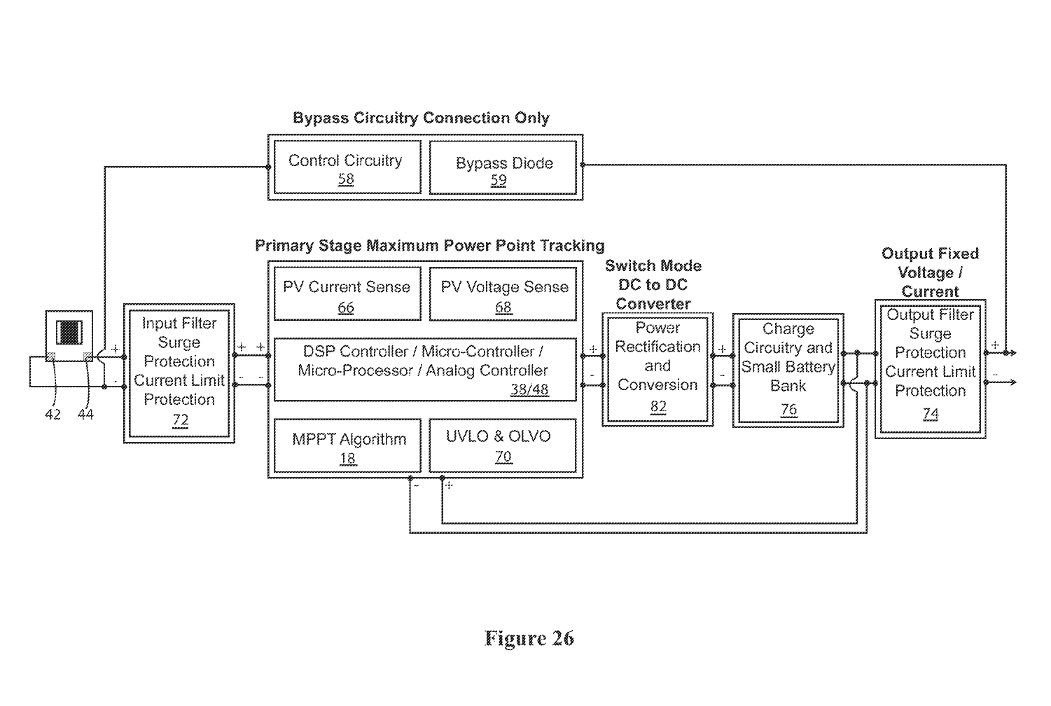

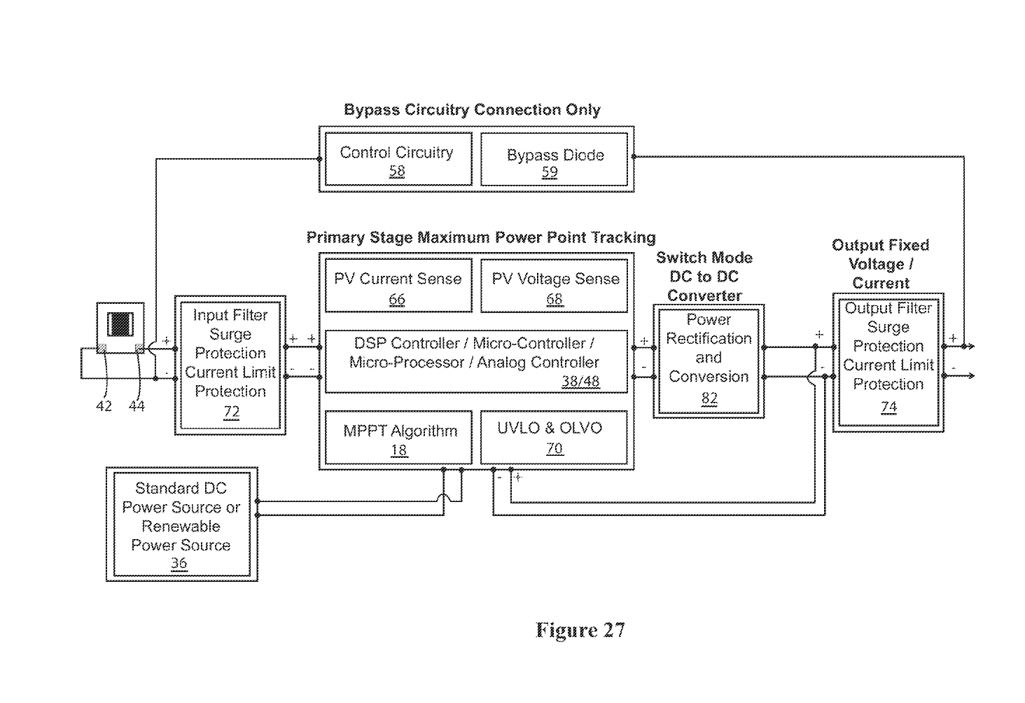

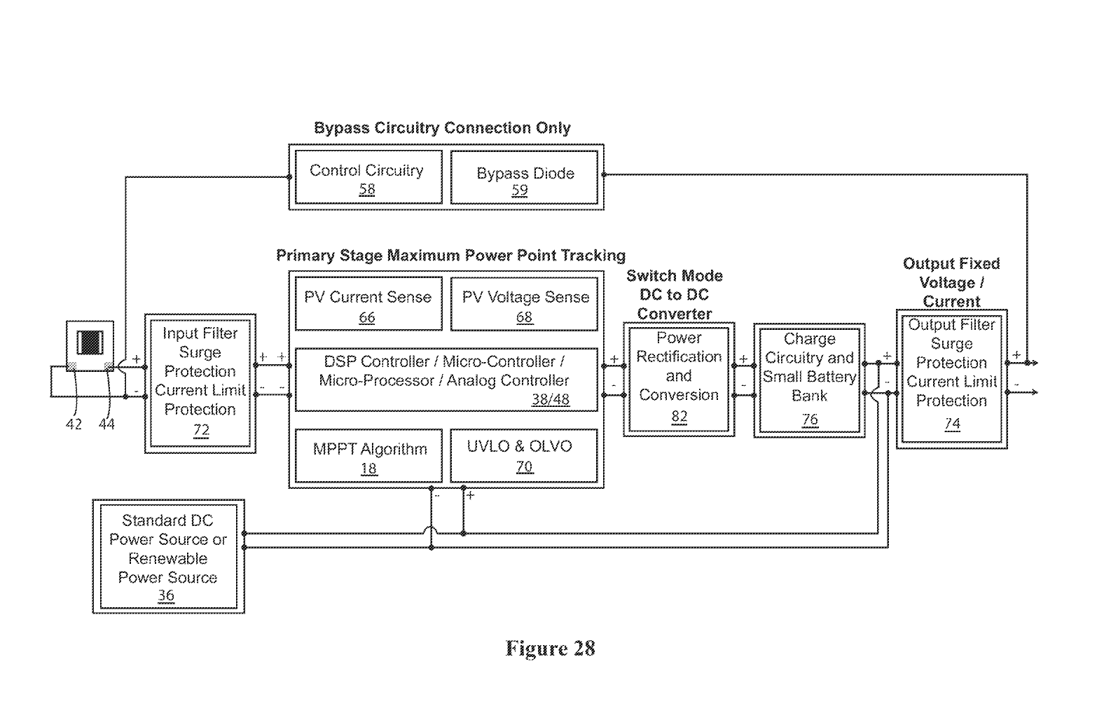

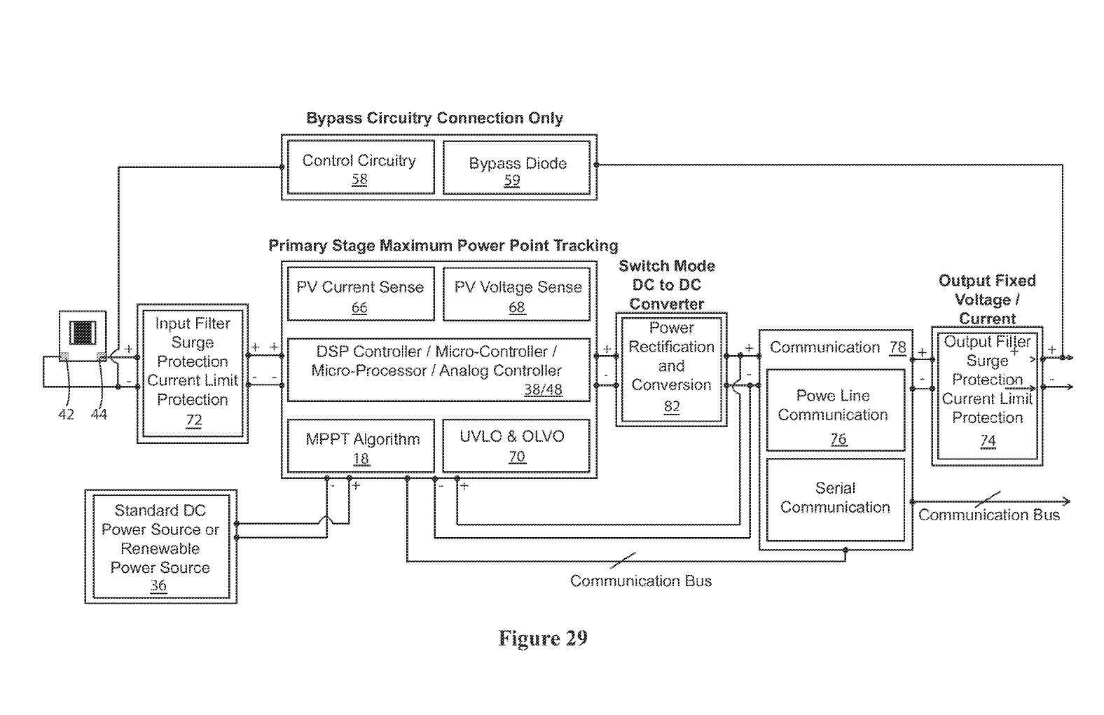

The IPEO 8 receives electrical power transmitted from the PV cell 6, tracks the MPP of the optical module 16 and converts the input power 50 to either a constant current or a constant voltage power supply 52. The IPEO 8 system therefore comprises an MPPT controller 54 and a power conversion controller 56, and may also comprise a bypass controller 58, a communication controller 60, system protection schemes 64 and/or an auxiliary power source 62, as shown in FIG. 25. Examples of circuit configurations that may be used to implement IPEOs 8 are shown in the block diagrams of FIGS. 26-29.

The MPPT controller 54 tracks the MPP by sensing the input voltage and current using sensors 66, 68 and analysing the input voltage and current from the PV cell, and locks the input voltage and current to the optical module's MPP. Any appropriate MPPT control algorithm 18 may be used. Examples of MPPT control algorithms include: perturb and observe, incremental conductance, constant voltage, and current feedback.

The power conversion controller 56 may comprise a rectifier and DC/DC converter 82 to convert a variable non-constant current and a non-constant voltage input to a constant voltage or constant current for supply to an electrical bus.

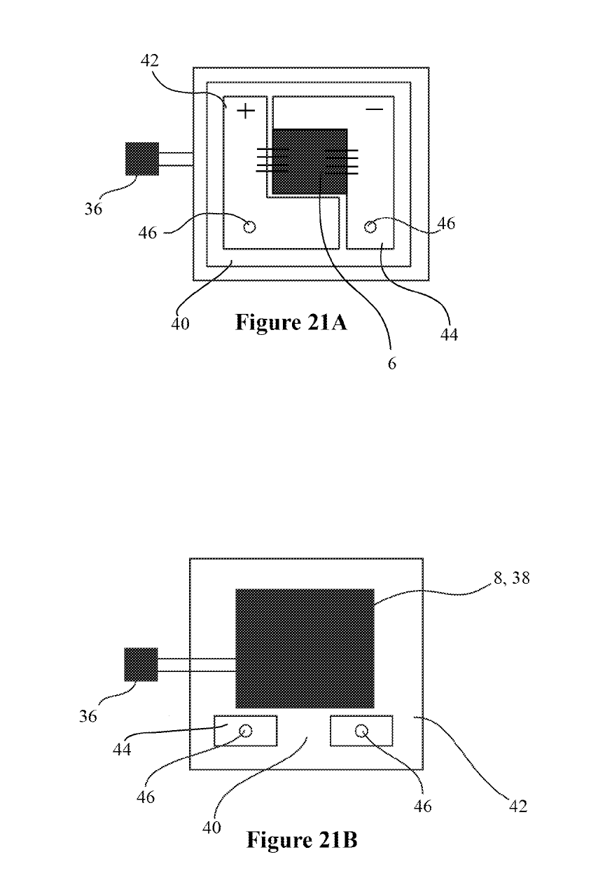

Any power source can power the active components on the receiver assembly 10. In one embodiment, an auxiliary power source, such as one or more batteries 76, can be used to power the active components of the receiver assembly 10. To take advantage of the optical elements of the integrated CPV module, the batteries 76 may be charged by solar power from one or more secondary PV cells 36 (as shown in FIGS. 21A and 21B) converted into electricity. Alternatively, the batteries 76 may be charged by the power bus of the system. One or more of the batteries 76 may be an on-board battery and the secondary PV cells 36 can be placed to capture diffused light under the primary or secondary optics of the optical concentrator 4. The auxiliary power source 62 may include an auxiliary power controller to control the supply of power to the chips 48 or SoC 38 from an on-board battery, an electrical power bus and/or directly from a secondary PV cell 36.

The system protection schemes 64 may include undervoltage-lockout (UVLO) and overvoltage-lockout (OVLO) circuitry 70, input and output filters for surge and current limit protection 72, 74.

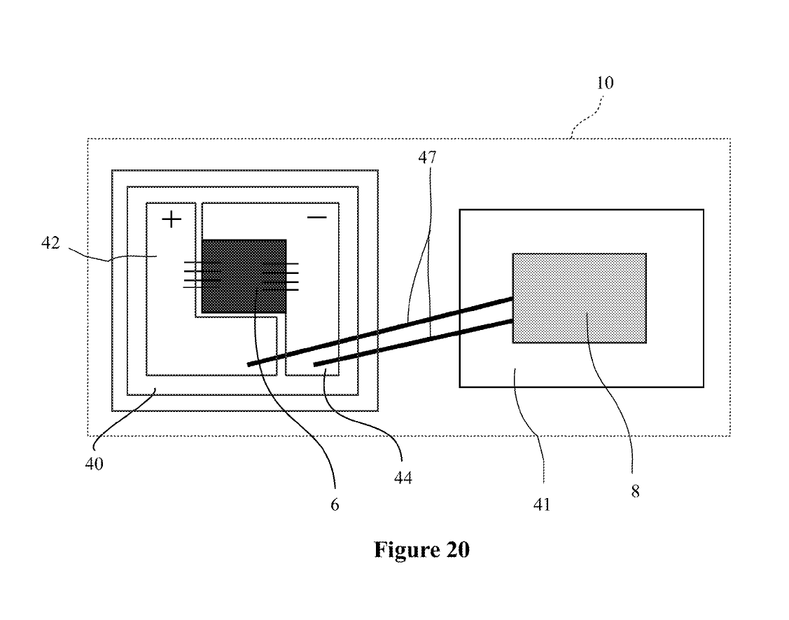

The IPEO 8 may also have communication circuitry 78 comprising a communication controller 60 and a communication bus 80 (an embodiment of which is shown in FIG. 20) for communication of control signals and data internal to the IPEO 8, with other integrated CPV modules and/or a central controller. The data communicated may include measurement data such as performance indicators and power generated.

It will be apparent to those skilled in the art that although the many of the embodiments described herein comprise an optical concentrator 4, the receiver assembly 10 can work without a concentrator optically coupled to the PV cell 6.

Various embodiments of the present invention having been thus described in detail by way of example, it will be apparent to those skilled in the art that variations and modifications may be made without departing from the invention. The invention includes all such variations and modifications as fall within the scope of the appended claims.

1. A photovoltaic power generation system comprising:
a plurality of photovoltaic strings, at least one of the strings being a string of integrated photovoltaic cell modules, each module comprising a photovoltaic cell and a primary stage power efficiency optimizer in electrical communication with the photovoltaic cell, the primary stage power efficiency optimizer configured to adjust an output voltage and current of the photovoltaic cell to reduce loss of output power of the string resulting from differences in output from the integrated photovoltaic cell modules of the string;
a plurality of secondary stage power efficiency optimizers, each secondary stage power efficiency optimizer electrically connected to at least one of the photovoltaic strings and configured to adjust an output voltage and current of the at least one photovoltaic string to reduce loss of output power of the system resulting from differences in output of the strings, and at least one of the secondary stage power efficiency optimizers being electrically connected to at least one of the at least one string of integrated photovoltaic cell modules; and
a central inverter electrically connected to the plurality of secondary stage power efficiency optimizers.

2. The photovoltaic power generation system of claim 1, wherein at least one of the strings electrically connected to one of the secondary stage power efficiency optimizers comprises non-concentrated integrated photovoltaic cell modules.

3. The photovoltaic power generation system of claim 1, wherein at least one of the integrated photovoltaic cell modules further comprises an optical concentrator.

4. The photovoltaic power generation system of claim 3, wherein the optical concentrator comprises at least one focusing element and a light guide which guides light toward the photovoltaic cell.

5. The photovoltaic power generation system of claim 1, wherein the primary stage power efficiency optimizer and the photovoltaic cell are integrated on a receiver assembly having a substrate on which the photovoltaic cell and the primary stage power efficiency optimizer are mounted, and wherein the primary stage power efficiency optimizer is disposed proximate to the photovoltaic cell.

6. The photovoltaic power generation system of claim 1, wherein the primary stage power efficiency optimizer further comprises components selected from the group of power conversion controller, bypass controller, communication controller, system protection controller, auxiliary power source, or any combination thereof.

7. The photovoltaic power generation system of claim 1, wherein the primary stage power efficiency optimizer comprises at least one of a voltage sensor for detecting the voltage produced by the photovoltaic cell and a current sensor for detecting the current produced by the photovoltaic cell.

8. The photovoltaic power generation system of claim 1, wherein each primary stage power efficiency optimizer adjusts the output voltage and current of the photovoltaic cell with which the primary stage power efficiency optimizer is in electrical communication as the output of the photovoltaic cell varies over time.

9. The photovoltaic power generation system of claim 1, wherein at least one of: (i) at least one of the primary stage power efficiency optimizers and (ii) at least one of the secondary stage power efficiency optimizers, comprise a maximum point tracker and a DC/DC converter.

10. The photovoltaic power generation system of claim 1, wherein the at least one of the primary stage power efficiency optimizer and the secondary stage power efficiency optimizer comprises control circuitry, a system-on-a-chip controller, or a microcontroller.

11. The photovoltaic power generation system of claim 1, wherein at least some of the primary stage power efficiency optimizers comprise a bypass mechanism.

12. The photovoltaic power generation system of claim 1, wherein at least some of the secondary stage power efficiency optimizers comprise a bypass mechanism.

13. The photovoltaic power generation system of claim 1, wherein at least one of: (i) the primary stage power efficiency optimizers, and (ii) the secondary stage power efficiency optimizers, are powered by at least one corresponding secondary photovoltaic cell.

14. The photovoltaic power generation system of claim 1, wherein one or more strings of photovoltaic cell modules are arranged on at least one solar panel.

15. The photovoltaic power generation system of claim 14, further comprising a local control unit near the solar panel, the local control unit containing the at least one secondary stage power efficiency optimizer.

16. A method for conversion of solar power to electrical power by a system comprising a plurality of strings of photovoltaic cells, the method comprising:
converting solar energy into electricity with the photovoltaic cells;
for at least one of the strings, simultaneously adjusting an output voltage and current of each photovoltaic cell of the string to reduce loss of output power of the string resulting from at least one of voltage and current differences amongst the photovoltaic cells of the string; and
simultaneously adjusting an output voltage and current of each string to reduce loss of power of the system resulting from at least one of voltage and current differences amongst the plurality of strings.

17. The method of claim 16, further comprising, for each photovoltaic cell of the at least one string, concentrating sunlight through a corresponding optical concentrator onto the photovoltaic cell.

18. The method of claim 16, wherein adjusting an output voltage and current of each photovoltaic cell comprises sensing an output current and an output voltage of the photovoltaic cell and locking one of the output current or output voltage of the photovoltaic cell to the maximum power point of the photovoltaic cell.

19. The method of claim 16, wherein adjusting an output voltage and current of each string comprises sensing an output current and an output voltage of the string and locking one of the output current or output voltage of the string to the maximum power point of the string.

20. The method of claim 16, further comprising converting the DC power from the strings to AC power.
